(19) United States
(12) Patent Application Publication
(10) Pub. No.: US 2025/0046732 A1
(43) Pub. Date: Feb. 6, 2025

(54) MANUFACTURING METHOD OF SEMICONDUCTOR DEVICE, SEMICONDUCTOR WAFER AND SEMICONDUCTOR DEVICE

(71) Applicant: ROHM CO., LTD., Kyoto (JP)

(72) Inventor: Ryuta KIMURA, Kyoto (JP)

(73) Assignee: ROHM CO., LTD., Kyoto (JP)

(21) Appl. No.: 18/788,765

(22) Filed: Jul. 30, 2024

(30) Foreign Application Priority Data
Aug. 3, 2023 (JP) 2023-126933

(51) Int. Cl. H01L 23/544; H01L 21/67; H01L 21/68

(52) U.S. Cl. CPC H01L 23/544; H01L 21/67092; H01L 21/67282; H01L 21/68

(57) ABSTRACT

The present disclosure provides a method for manufacturing a semiconductor device, comprising: a first process of forming a first layer on a main surface of a wafer, wherein the first layer has a reference mark for measuring a positional deviation of a resist relative to a first element pattern for a semiconductor element; a second process of forming the resist on the first layer to cover the reference mark and the first element pattern; a third process of exposing and developing the resist to form a positional deviation determination pattern overlapping the reference mark in a plan view; a peripheral pattern surrounding the positional deviation determination pattern in the plan view; and a second element pattern for the semiconductor element; and a fourth process of determining a positional deviation of the second element pattern with respect to the first element pattern.

### TECHNICAL FIELD

The present disclosure relates to a method for manufacturing a semiconductor device, a semiconductor wafer and a semiconductor device.

### BACKGROUND

Patent publication 1 discloses a semiconductor device including a first trench structure and a second trench structure, the first trench structure including a chip having a first main surface on one side and a second main surface on the other side; a first region of a first conductivity type, formed on the side of the second main surface in the chip; a second region of a second conductivity type, formed on the side of the first main surface in the chip, wherein the first region and the second region form a p-n junction; a device region, disposed on the first main surface; a first trench, passing through the p-n junction from the first main surface; a first insulating film, exposing the first region from a wall surface of the first trench; and a first polycrystalline silicon, separated by the first insulating film to be buried in the first trench; the first trench structure dividing the device region. The second trench structure includes: a second trench, passing through the p-n junction from the first main surface; a second insulating film, exposing the first region from a wall surface of the second trench; and a second polycrystalline silicon separated by the second insulating film to be buried in the second trench; the second trench structure dividing the device region on the side closer to the device region than the first trench structure.

### PRIOR ART DOCUMENT

Patent publication
[Patent document 1] Japan Patent Publication No. 2023-32332

### BRIEF DESCRIPTION OF THE DRAWINGS

FIG. 1 is brief diagram of a piece of wafer for manufacturing a semiconductor device.

FIG. 2 is an enlarged diagram of a main part of the wafer in FIG. 1.

FIG. 3 is a diagram of an element structure formed at the wafer.

FIG. 4A is a diagram of an example of a method for manufacturing the semiconductor device.

FIG. 4B is a diagram of a subsequent process of that in FIG. 4A.

FIG. 4C is a diagram of a subsequent process of that in FIG. 4B.

FIG. 4D is a diagram of a subsequent process of that in FIG. 4C.

FIG. 4E is a diagram of a subsequent process of that in FIG. 4D.

FIG. 4F is a diagram of a subsequent process of that in FIG. 4E.

FIG. 4G is a diagram of a subsequent process of that in FIG. 4F.

FIG. 4H is a diagram of a subsequent process of that in FIG. 4G.

FIG. 4I is a diagram of a subsequent process of that in FIG. 4H.

FIG. 4J is a diagram of a subsequent process of that in FIG. 4I.

FIG. 4K is a diagram of a subsequent process of that in FIG. 4J.

FIG. 4L is a diagram of a subsequent process of that in FIG. 4K.

FIG. 4M is a diagram of a subsequent process of that in FIG. 4L.

FIG. 4N is a diagram of a subsequent process of that in FIG. 4M.

FIG. 4O is a diagram of a subsequent process of that in FIG. 4N.

FIG. 4P is a diagram of a subsequent process of that in FIG. 4O.

FIG. 5A is a diagram of a planar pattern (a first method) of a first resist film.

FIG. 5B is a diagram of a section pattern (a first method) of a first resist film.

FIG. 6A is a diagram of a planar pattern (a second method) of a first resist film.

FIG. 6B is a diagram of a section pattern (a second method) of a first resist film.

FIG. 7A is a diagram of a planar pattern of a second resist film.

FIG. 7B is a diagram of a section pattern of a second resist film.

FIG. 8 is an enlarged diagram of a main part of the wafer after the element structure is formed.

FIG. 9 is an enlarged diagram of the part surrounded by the doubled-dotted line IX in FIG. 8.

FIG. 10 is a schematic plan view of the semiconductor device.

FIG. 11 is an enlarged diagram of the part surrounded by the doubled-dotted line XI in FIG. 10.

FIG. 12A is a diagram of measurement results of a positional deviation of a resist film in sample 1.

FIG. 12B is a diagram of measurement results of a positional deviation of a resist film in sample 2.

FIG. 13A is a diagram of an example of a method for manufacturing the semiconductor device.

FIG. 13B is a diagram of a subsequent process of that in FIG. 13A.

FIG. 13C is a diagram of a subsequent process of that in FIG. 13B.

FIG. 13D is a diagram of a subsequent process of that in FIG. 13C.

FIG. 13E is a diagram of a subsequent process of that in FIG. 13D.

FIG. 13F is a diagram of a subsequent process of that in FIG. 13E.

FIG. 14A is a diagram of an example of a method for manufacturing the semiconductor device.

FIG. 14B is a diagram of a subsequent process of that in FIG. 14A.

FIG. 14C is a diagram of a subsequent process of that in FIG. 14B.

FIG. 14D is a diagram of a subsequent process of that in FIG. 14C.

FIG. 14E is a diagram of a subsequent process of that in FIG. 14D.

FIG. 14F is a diagram of a subsequent process of that in FIG. 14E.

FIG. 15 is a diagram of a section pattern (a third method) of a first photoresist film.

FIG. 16 is a diagram of a planar pattern (a fourth method) of a first resist film.

### DETAILED DESCRIPTION OF THE EMBODIMENTS

### Detailed Description

Details of embodiments of the present disclosure are given with the accompanying drawings below.

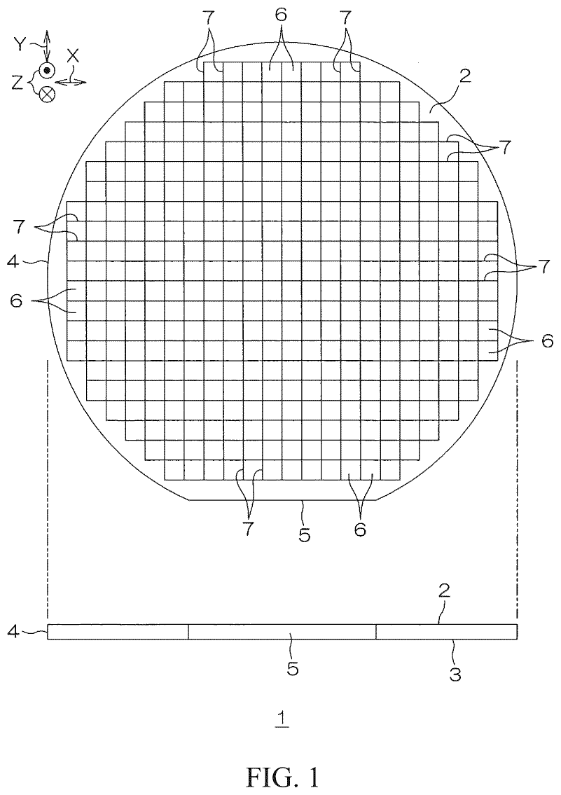

FIG. 1 shows brief diagram of a piece of wafer 1 for manufacturing a semiconductor device 100.

The wafer 1 can also be a piece of semiconductor wafer such as silicon (Si), silicon carbide (SiC), gallium nitride (GaN), diamond (C), or gallium oxide (Ga₂O₃). The wafer 1 is formed as a flat disc. The wafer 1 can also be formed as a flat cuboid. The wafer 1 has a first wafer main surface 2 on one side, a second wafer main surface 3 on the other side, and a wafer side surface 4 connecting the first wafer main surface 2 and the second wafer main surface 3.

The wafer 1 has a mark 5 indicating crystal orientation of the wafer 1 on the wafer side surface 4. The mark 5 includes either one or both of an orientation plane and an orientation notch. The orientation plane includes a notch linearly cut out in a plan view. The orientation notch includes a notch portion cut out from a recessed shape (for example, a slender shape) at a central portion of the first wafer main surface 2.

For example, multiple element regions 6 and multiple cutting predetermined lines 7 are configured in the wafer 1. Each element region 6 is a region corresponding to the final semiconductor device 100 (to be described shortly) obtained. Each element region 6 is configured to be in quadrilateral shape in the plan view.

In the method above, the multiple element regions 6 are arranged in a matrix along a first direction X and a second direction Y in the plan view. The multiple element regions 6 are configured to be spaced inward from a periphery of the first wafer main surface 2 in the plan view. The multiple cutting predetermined lines 7 are arranged in grid shape extending along the first direction X and the second direction Y to divide the multiple element regions 6.

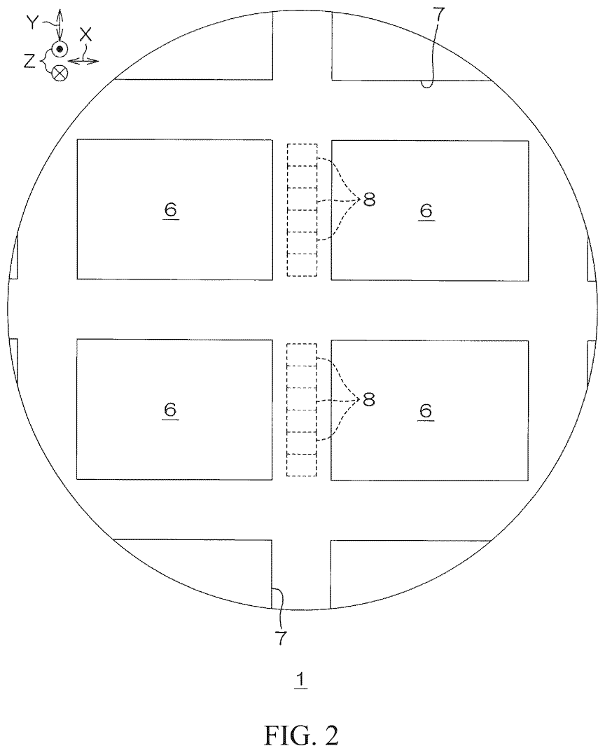

FIG. 2 shows an enlarged diagram of a main part of the wafer 1 in FIG. 1.

Referring to FIG. 2, the cutting predetermined lines 7 are formed as strip regions with a constant width. The cutting predetermined lines 7 can also be referred to as “cutting predetermined regions”. Determination mark regions 8 are formed in the cutting predetermined lines 7. Determination marks for determining the presence of positional deviation during a process of forming an element structure are formed in the determination mark regions 8.

For example, during the process of forming the element structure, multiple layers of the element regions 6 are laminated on the first wafer main surface 2. Impurity regions, wiring layers and contact vias are formed according to a designed pattern for each layer. Each layer is separately patterned (for example, by photolithography). When a positional deviation occurs between upper and lower layers, issues such as poor connection is resulted, so it is necessary to determine whether a positional deviation occurs between layers. The determination marks are used for determining the presence of the positional deviation.

In the method above, the multiple determination mark regions 8 are formed on the cutting predetermined lines 7. Parts of the multiple determination mark regions 8 sandwiched by adjacent element regions 6 are arranged in alignment along a lengthwise direction of the cutting predetermined lines 7. For a positional deviation determination mark of a group including an upper layer and a lower layer connected to each other, one determination mark region 8 is allocated. For example, one determination mark region 8 is allocated to the positional deviation determination mark between the first layer and the second layer, and another determination mark region 8 is allocated to the positional deviation determination mark between the second layer and the third layer.

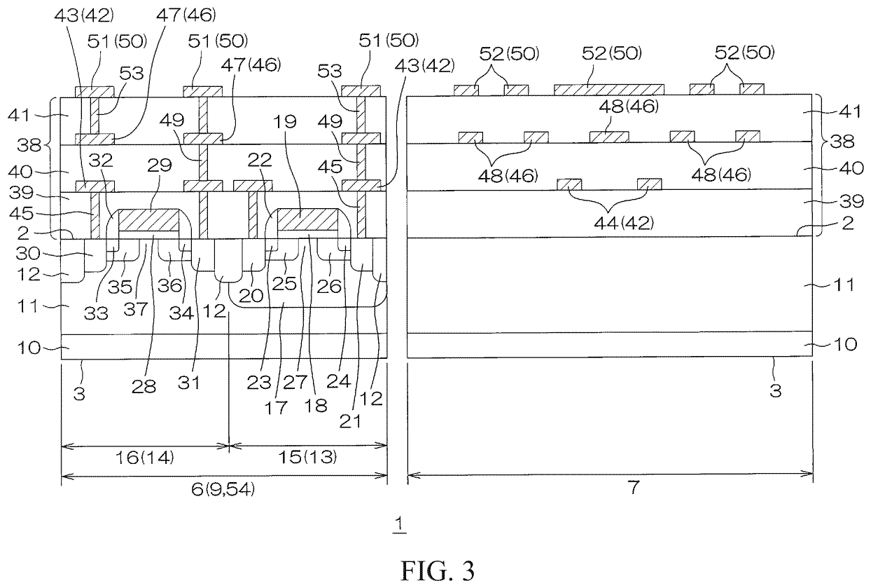

FIG. 3 shows a diagram of an element structure 54 formed on the wafer 1. Multiple functional elements are formed in the element region 6. The multiple functional elements can be, for example, large scale integration (LSI). Such functional elements are, for example, a complementary metal insulator semiconductor (CMIS), a bipolar junction transistor (BJT), an insulated gate bipolar transistor (IGBT), a junction field effect transistor (JFET), a non-volatile memory, a capacitor or a resistor. As an example of these element structures 54, the structure of a CMIS transistor 9 is given as an example in FIG. 3.

The wafer 1 includes a substrate 10 and an epitaxial layer 11. The substrate 10 can be a p-type silicon substrate. An impurity concentration of the substrate 10 can be, for example, between about 1.0×10¹³ cm⁻³ and about 1.0×10²⁰ cm⁻³. The epitaxial layer 11 can also be an n-type silicon semiconductor layer in the method above. The epitaxial layer 11 is laminated on the substrate 10. An impurity concentration of the epitaxial layer 11 can be, for example, between about 1.0×10¹³ cm⁻³ and about 1.0×10¹⁷ cm⁻³.

In the element region 6, an element separating portion 12 dividing a region on the first wafer main surface 2 into multiple active regions is formed in the epitaxial layer 11. The element separating portion 12 can be, for example, a shallow trench isolation (STI) structure. In FIG. 3, an n-side active region 15 for an n-type first MISFET 13 and a p-side active region 16 for a p-type second MISFET 14 are separated by the element separating portion 12. By connecting the first MISFET 13 and the second MISFET 14 in a complementary manner, the CMIS transistor 9 is formed.

A p-type well 17 is formed on the first wafer main surface 2 in the n-side active region 15. An impurity concentration of the p-type well 17 is greater than the impurity concentration of the epitaxial layer 11, and can be, for example, between about 1.0×10¹⁷ cm⁻³ and about 1.0×10¹⁹ cm⁻³.

In the n-side active region 15, an n-side planar gate structure is formed in the first wafer main surface 2 of the epitaxial layer 11. The n-side planar gate structure includes an n-side gate insulating film 18 and an n-side gate electrode 19 sequentially laminated from the side of the first wafer main surface 2. The n-side gate insulating film 18 can include a silicon oxide (SiO₂) film. Preferably, the n-side gate insulating film 18 includes a SiO₂ film containing an oxide of the epitaxial layer 11. Preferably, the n-side gate electrode 19 includes a conductive polycrystalline silicon.

On a surface portion of the p-type well 17, an n-type source region 20 and an n-type drain region 21 are formed with a space in between. Impurity concentrations of the n-type source region 20 and the n-type drain region 21 are greater than the impurity concentration of the p-type well 17, and can be, for example, between about 1.0×10¹⁹ cm⁻³ and about 1.0×10²¹ cm⁻³. The n-type source region 20 and the n-type drain region 21 are formed in self-alignment with respect to an n-side sidewall 22.

An n-type source extension region 23 and an n-type drain extension region 24 respectively extending integrally from the n-type source region 20 and the n-type drain region 21 are further formed in the n-side active region 15. Impurity concentrations of the n-type source extension region 23 and the n-type drain extension region 24 are less than impurity concentrations of the n-type source region 20 and the n-type drain region 21, and can be, for example, between about 1.0×10¹⁸ cm⁻³ and about 1.0×10²¹ cm⁻³. The n-type source extension region 23 and the n-type drain extension region 24 are formed in self-alignment with respect to an n-side gate electrode 19.

A p-type source sac-like implantation region 25 and a p-type drain sac-like implantation region 26 respectively extending integrally from the n-type source region 20 and the n-type drain region 21 are further formed in the n-side active region 15. Impurity concentrations of the p-type source sac-like implantation region 25 and the p-type drain sac-like implantation region 26 are greater than the impurity concentration of the p-type well 17, and can be, for example, between about 1.0×10¹8 cm⁻³ and about 1.0×10²¹ cm⁻³. The p-type source sac-like implantation region 25 and the p-type drain sac-like implantation region 26 horizontally pass through a border between the n-side sidewall 22 and the n-side gate electrode 19, and is separated by the n-side gate insulating film 18 to face the n-side gate electrode 19.

The p-type source sac-like implantation region 25 and the p-type drain sac-like implantation region 26 respectively cover bottoms and sides of the n-type source extension region 23 and the n-type drain extension region 24. In a central portion of the n-side active region 15, a region sandwiched between the p-type source sac-like implantation region 25 and the p-type drain sac-like implantation region 26 is an n-side channel region 27 formed by a portion of the p-type well 17. The n-side gate electrode 19 is separated by the n-side gate insulating film 18 to face the n-side channel region 27.

In the p-side active region 16, a p-side planar gate structure is formed in the first wafer main surface 2 of the epitaxial layer 11. The p-side planar gate structure includes a p-side gate insulating film 28 and a p-side gate electrode 29 sequentially laminated from the side of the first wafer main surface 2. The p-side gate insulating film 28 can include a silicon oxide (SiO₂) film. Preferably, the p-side gate insulating film 28 includes a SiO₂ film containing an oxide of the epitaxial layer 11. Preferably, the p-side gate electrode 29 includes a conductive polycrystalline silicon.

On the epitaxial layer 11, a p-type source region 30 and a p-type drain region 31 are formed with a space in between. Impurity concentrations of the p-type source region 30 and the p-type drain region 31 are greater than an impurity concentration of an n-type well, and can be, for example, between about 1.0×10¹⁹ cm⁻³ and about 1.0×10²¹ cm⁻³. The p-type source region 30 and the p-type drain region 31 are formed in self-alignment with respect to an n-side sidewall 32.

A p-type source extension region 33 and a p-type drain extension region 34 respectively extending integrally from the p-type source region 30 and the p-type drain region 31 are further formed in the p-side active region 16. Impurity concentrations of the p-type source extension region 33 and the p-type drain extension region 34 are less than impurity concentrations of the p-type source region 30 and the p-type drain region 21, and can be, for example, between about 1.0×10¹⁸ cm⁻³ and about 1.0×10²¹ cm⁻³. The p-type source extension region 33 and the p-type drain extension region 34 are formed in self-alignment with respect to the p-side gate electrode 29.

An n-type source sac-like implantation region 35 and an n-type drain sac-like implantation region 36 respectively extending integrally from the p-type source region 30 and the p-type drain region 31 are further formed in the p-side active region 16. Impurity concentrations of the n-type source sac-like implantation region 35 and the n-type drain sac-like implantation region 36 are greater than the impurity concentration of the epitaxial layer 11, and can be, for example, between about 1.0×1018 cm⁻³ and about 1.0×10²⁰ cm⁻³. The n-type source sac-like implantation region 35 and the n-type drain sac-like implantation region 36 horizontally pass through a border between the p-side sidewall 32 and the p-side gate electrode 29, and is separated by the p-side gate insulating film 28 to face the n-side gate electrode 19.

The n-type source sac-like implantation region 35 and the n-type drain sac-like implantation region 26 respectively cover bottoms and sides of the p-type source extension region 33 and the p-type drain extension region 34. In a central portion of the p-side active region 16, a region sandwiched between the n-type source sac-like implantation region 35 and the n-type drain sac-like implantation region 36 is a p-side channel region 37 formed by a portion of the epitaxial layer 11. The p-side gate electrode 29 is separated by the p-side gate insulating film 28 to face the p-side channel region 37.

An interlayer insulating layer 38 is formed in the first wafer main surface 2 of the epitaxial layer 11. The interlayer insulating layer 38 covers an entirety of the element regions 6 and the cutting predetermined lines 7. The interlayer insulating film 38 includes multiple insulating films 39 to 41. In the method above, a first insulating layer 39, a second insulating layer 40 and a third insulating layer 41 sequentially laminated from the side of the first wafer main surface 2 are included. Each of the insulating layers 39 to 41 can include a SiO₂ film.

A first conductive layer 42 is formed on the first insulating layer 39. The first conductive layer 42 is covered by the second insulating layer 40. The first conductive layer 42 includes a first wiring layer 43 on the side of the element region 6 and a first outer layer 44 on the side of the cutting predetermined line 7. Some of the multiple first wiring layers 43 are electrically connected to the n-type source region 20, the n-type drain region 21, the p-type source region 30 and the p-type drain region 31 by a first channel electrode 45 embedded in the first insulating layer 39.

A second conductive layer 46 is formed on the second insulating layer 40. The second conductive layer 46 is covered by the third insulating layer 41. The second conductive layer 46 includes a second wiring layer 47 on the side of the element region 6 and a second outer layer 48 on the side of the cutting predetermined line 7. Some of the multiple second wiring layers 47 are electrically connected to the first wiring layer 43 by a second channel electrode 49 embedded in the second insulating layer 40.

A third conductive layer 50 is formed on the third insulating layer 41. The third conductive layer 50 includes a third wiring layer 51 on the side of the element region 6 and a third outer layer 52 on the side of the cutting predetermined line 7. Some of the multiple third wiring layers 51 are electrically connected to the second wiring layer 47 by a third channel electrode 53 embedded in the third insulating layer 41.

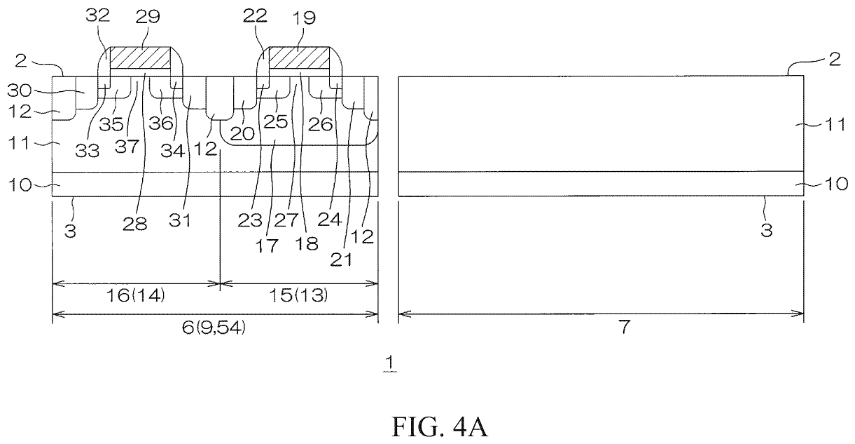

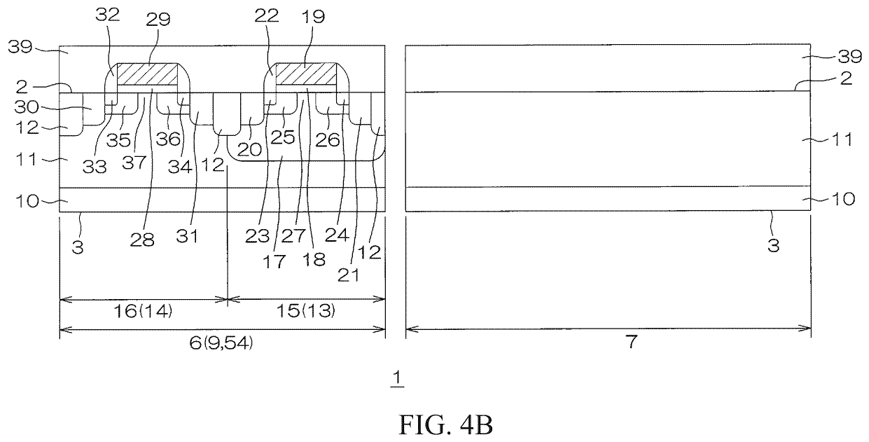

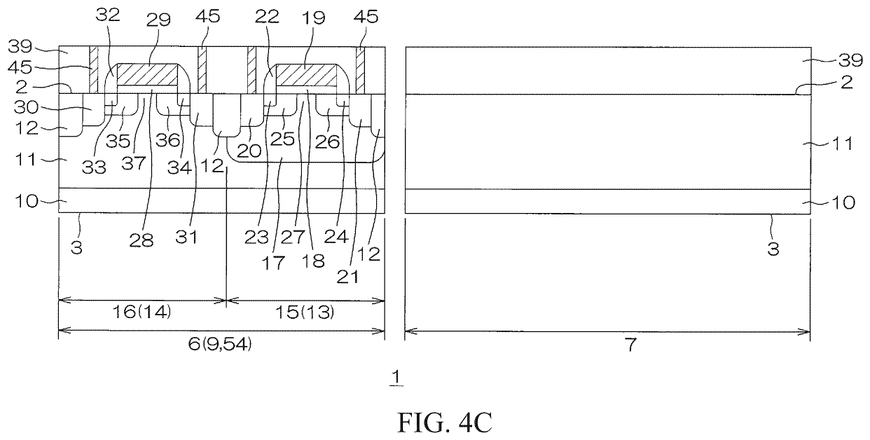

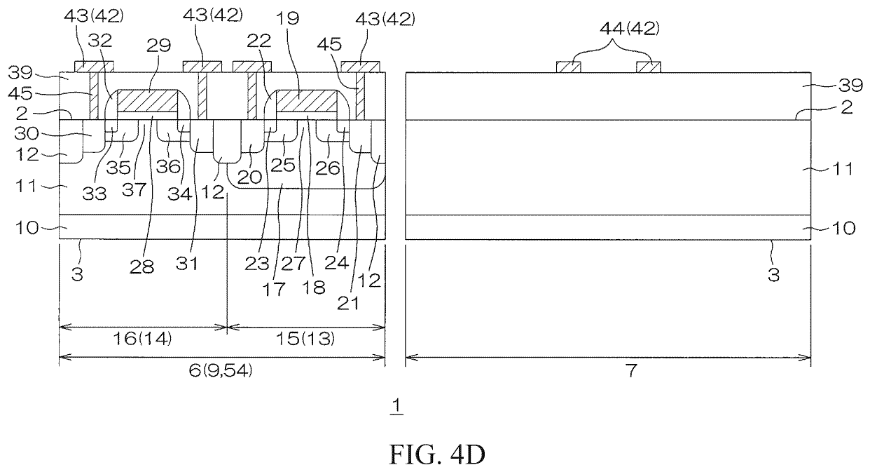

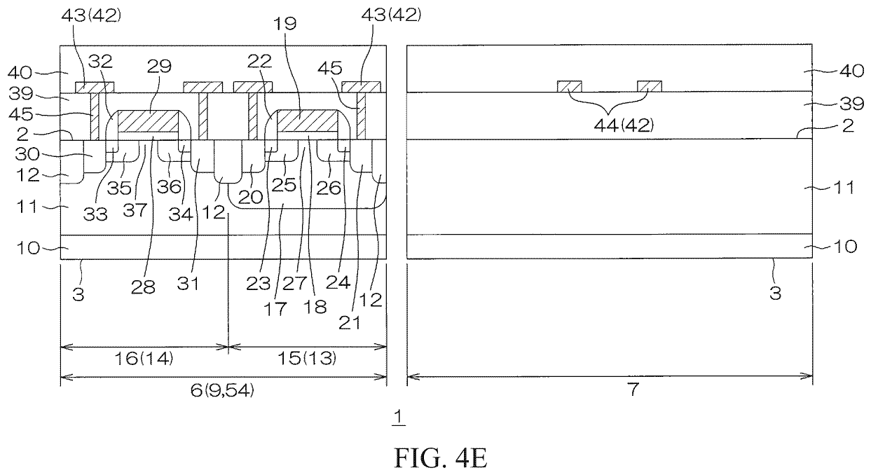

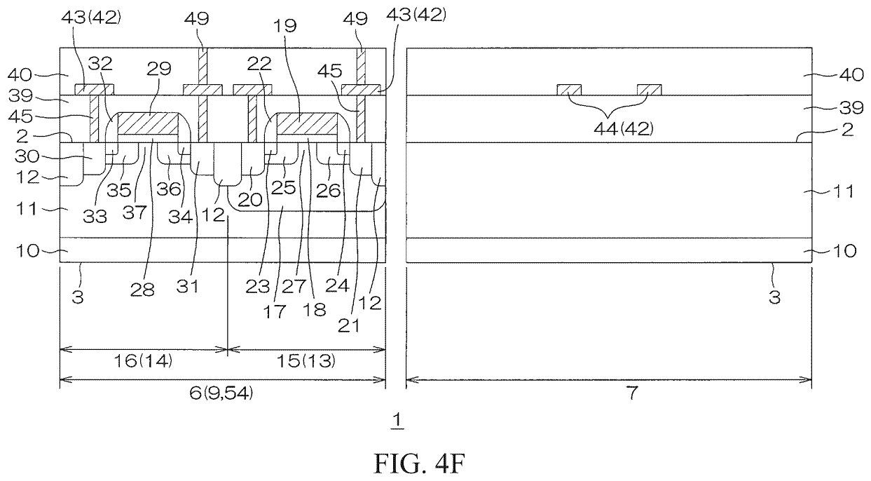

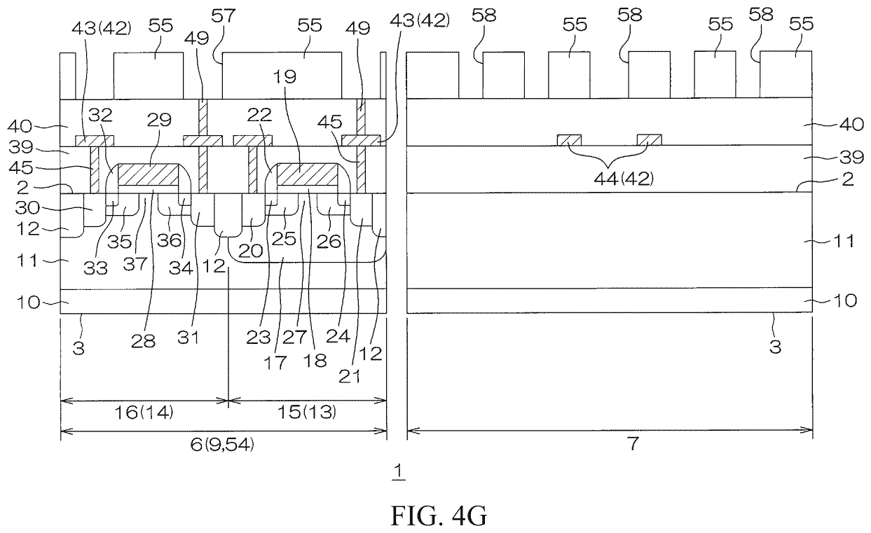

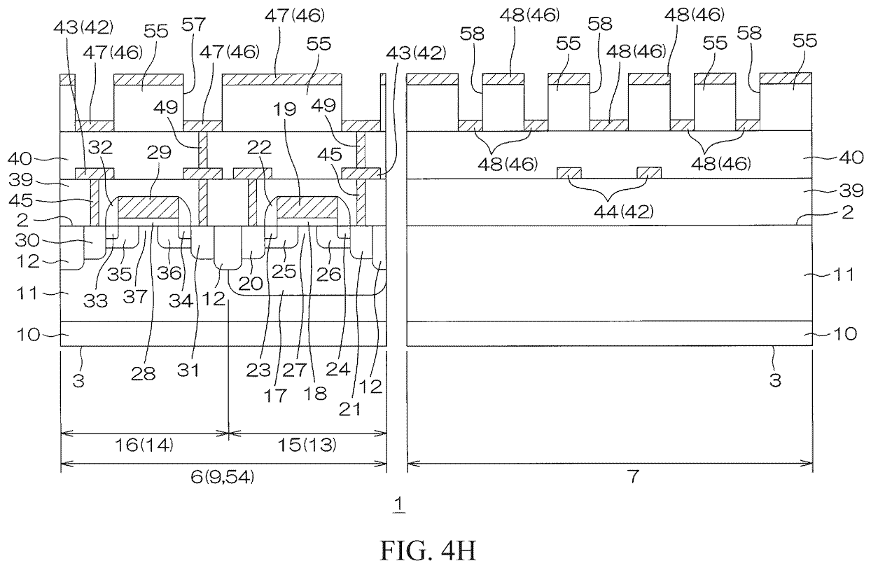

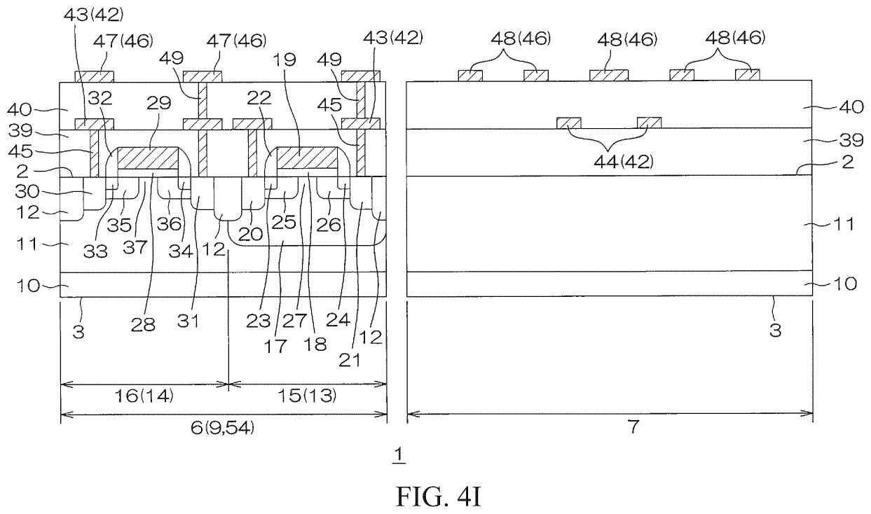

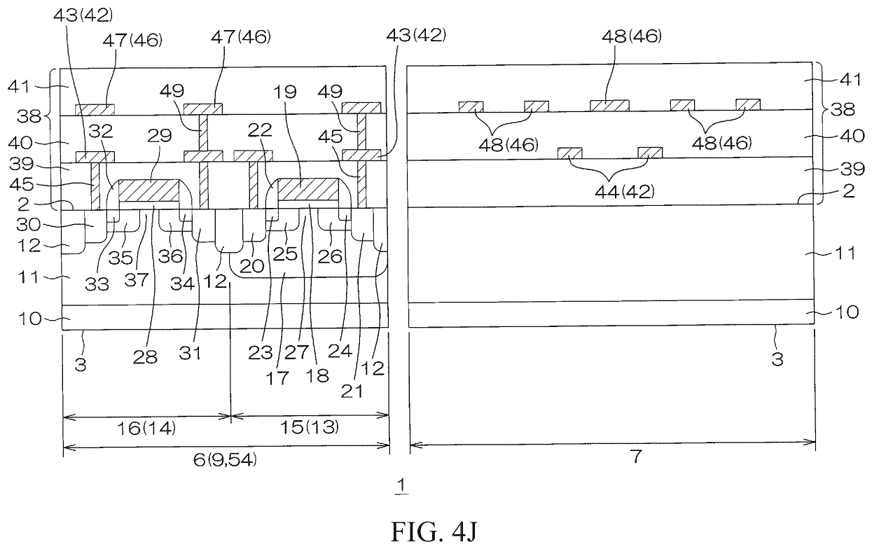

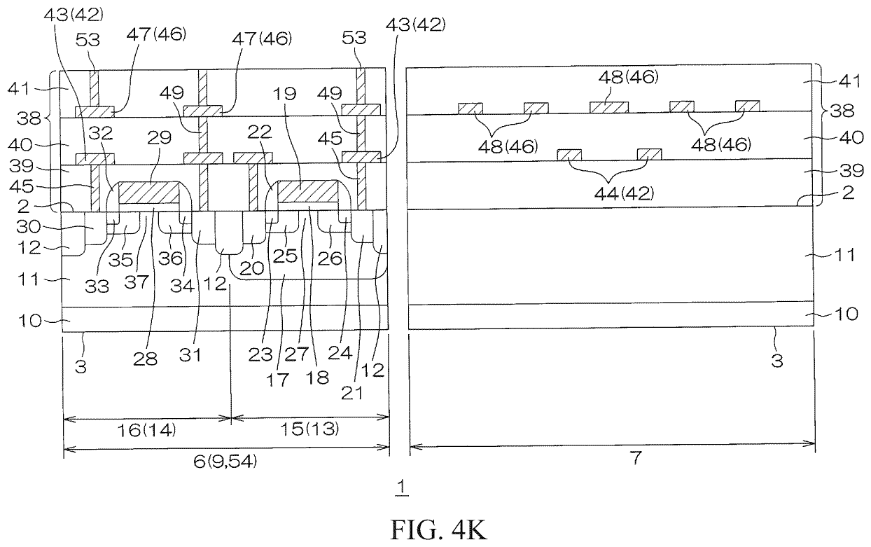

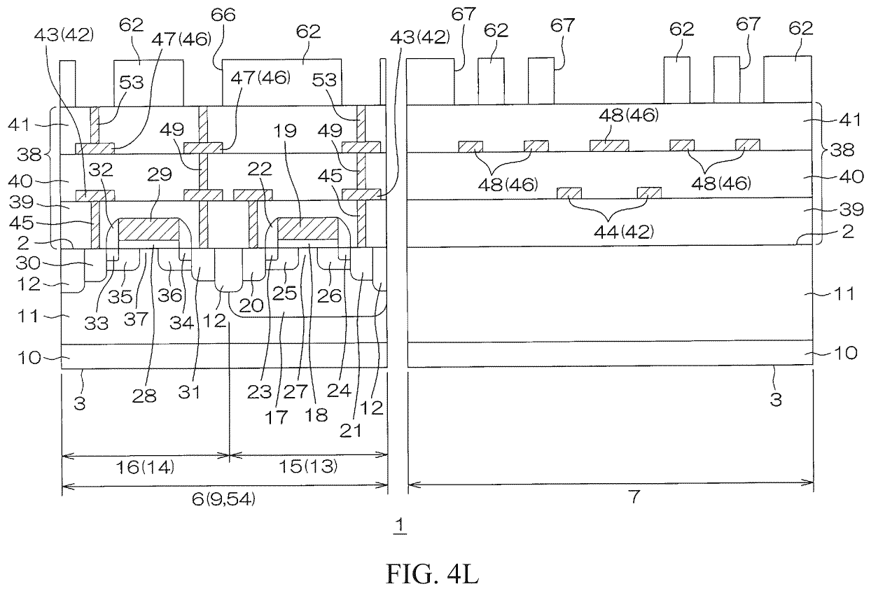

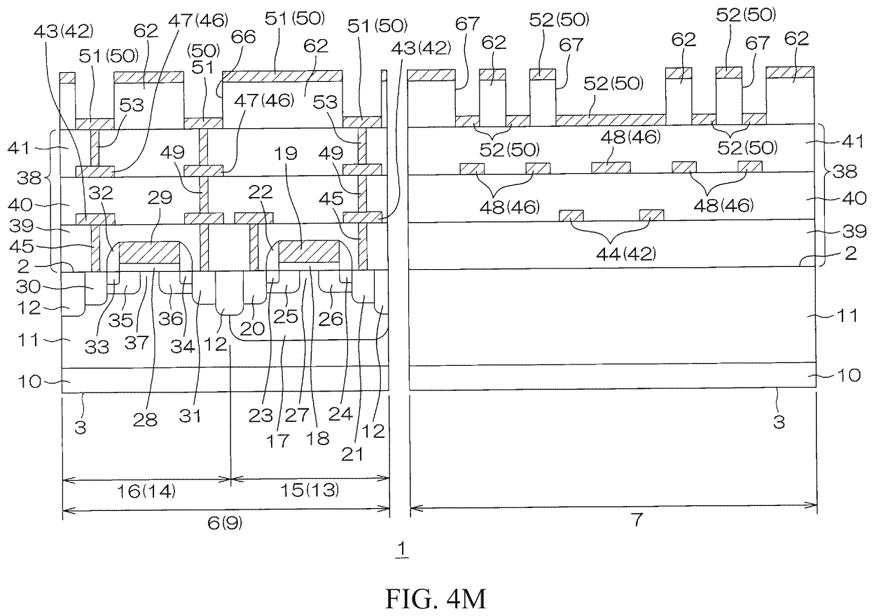

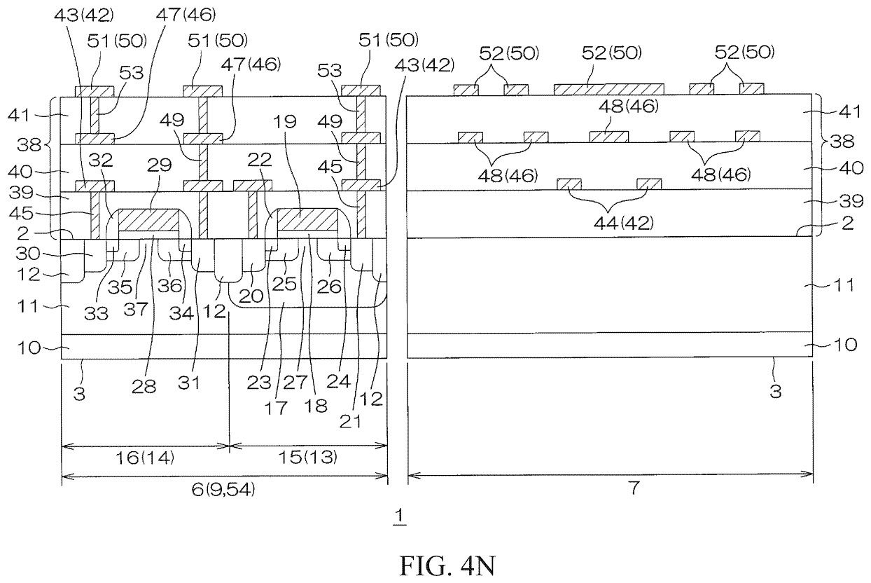

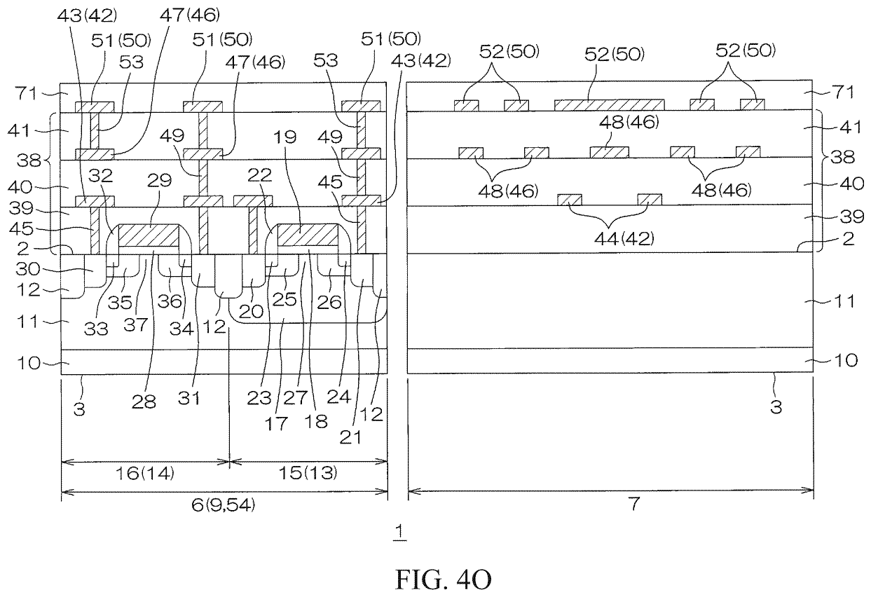

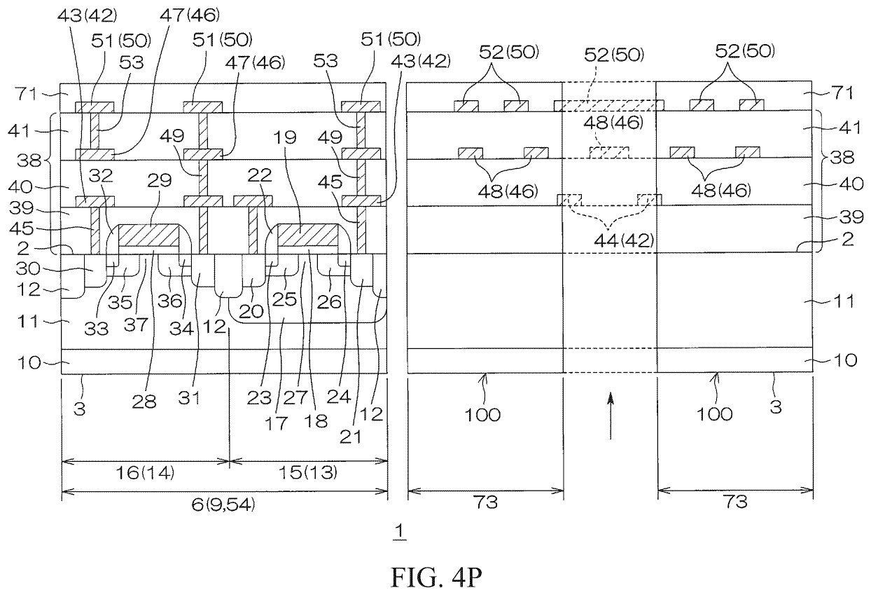

Next, referring to FIG. 4A to FIG. 4P, processes for forming the semiconductor device 100 in the element region 6 of the wafer 1 are described. FIG. 4A to FIG. 4P show diagrams of an example of a method for manufacturing the semiconductor device 100 according to an order of the processes. FIG. 4A to FIG. 4P depict section diagrams corresponding to the wafer 1 in FIG. 3.

Referring to FIG. 4A, after the element separating portion 12 is formed in the element region 6 of the wafer 1, the element structure 54 including the CMIS transistor 9 is formed. The impurity regions, the gate insulating films 18 and 28 and the gate electrodes 19 and 29 of the CMOS transistor 9 are formed by commonly known semiconductor manufacturing techniques.

Next, referring to FIG. 4B, the first insulating layer 39 as an example of a first layer is formed on the first wafer main surface 2 to cover the element structure 54 including the CMIS transistor 9. The first insulating layer 39 can be formed by means of, for example, plasma chemical vapor deposition (CVD).

Next, referring to FIG. 4C, the first channel electrode 45 is embedded into the first insulating layer 39. For example, multiple channel holes are selectively formed in the first insulating layer 39, and the channel holes are filled by a conductive material to accordingly form the first channel electrode 45. The first channel electrode 45 can also be formed of tungsten (W), for example.

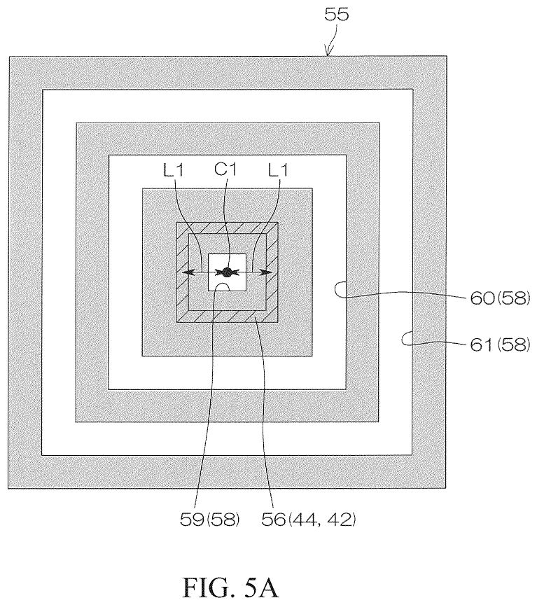

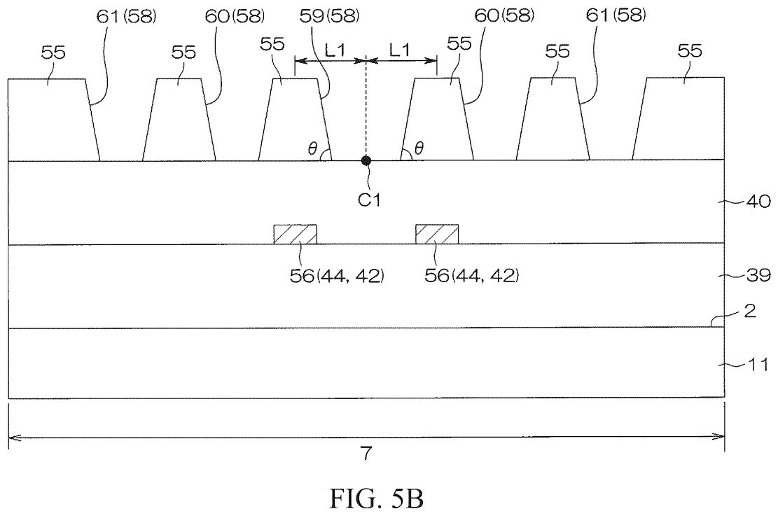

Next, referring to FIG. 5D, the first conductive layer 42 is formed on the first insulating layer 39. For example, by means of sputtering, a conductive material is deposited on the first insulating layer 39 and is then patterned, accordingly obtaining the first conductive layer 42 selectively formed on the first insulating layer 39. The first conductive layer 42 includes the first wiring layer 43 as an example of a first element pattern on the side of the element region 6 and the first outer layer 44 on the side of the cutting predetermined line 7.

Referring to FIG. 5A and FIG. 5B, processes for forming the first conductive layer 42 are to be described in detail herein. FIG. 5A and FIG. 5B are respectively diagrams of a planar pattern and a section pattern of the first resist film 55. FIG. 5B shows an enlarged structural diagram of the cutting predetermined line 7.

Referring to FIG. 5A and FIG. 5B, the first outer layer 44 is formed in ring shape in the plan view. The first outer layer 44 is a reference mark for positional deviation determination of the first resist film 5 in subsequent processes, and can also be referred to as a first reference mark 56. In the method above, the first reference mark 56 is a mark formed in ring shape in the plan view on a main surface of the first insulating layer 39. As shown in FIG. 5A, the first reference mark 56 can be a ring without ends or a ring having ends. The first reference mark 56 can be, for example, a ring having ends of which a part (for example, four corners) is divided, as shown in FIG. 5A. Moreover, the first reference mark 56 can be in quadrilateral ring shape as shown in FIG. 5A, or can be in perfectly circular ring shape, ellipsoidal shape or triangular shape.

Next, referring to FIG. 4E, the second insulating layer 40 is formed on the first insulating layer 39 to cover the first conductive layer 42. The second insulating layer 40 can be formed by means of CVD, for example.

Next, referring to FIG. 4F, the second channel electrode 49 is embedded into the second insulating layer 40. For example, multiple channel holes are selectively formed in the second insulating layer 40, and the channel holes are filled by a conductive material to accordingly form the second channel electrode 49. The second channel electrode 49 can also be formed of tungsten (W), for example.

Next, referring to FIG. 4G, the first resist film 55 is formed on the second insulating layer 40. The first resist film 55 indirectly covers the first wiring layer 43 and the first outer layer 44 across from the second insulating layer 40. The first resist film 55 can also be a commonly known resist (in either a positive or negative type). The thickness of the first resist film 55 is, for example, between about 35000 Å and about 40000 Å. For example, the material of the first resist film 55 is applied onto an entire surface of the second insulating layer 40 and then pre-baked, and the resist material is exposed. The resist material having been exposed is developed to obtain the first resist film 55. After the developing, a cleansing (cleaning) process and a post-baking process can also be performed as needed.

The first resist film 55 having been developed includes a first element-side opening 57 and a first outer opening 58. The first element-side opening 57 is consistent with a pattern of the second wiring layer 47. The first outer opening 58 is consistent with a pattern of the second outer layer 48.

Referring to FIG. 5A and FIG. 5B, the first outer opening 58 is described in detail herein. In FIG. 5A, the part of an opening of the first resist film 55 is indicated as unshaded, and the part of a film of the first resist film 55 is indicated as shaded. The first outer opening 58 includes a first determination pattern 59, a first peripheral pattern 60 and a second peripheral pattern 61. The first determination pattern 59, the first peripheral pattern 60 and the second peripheral pattern 61 can also be referred to as a first determination opening, a first peripheral opening and a second peripheral opening, respectively.

The first determination pattern 59 forms a region overlapping the first reference mark 56 in the plan view. The region overlapping the first reference mark 56 can be include both of a region in ring shape overlapping the first reference mark 56 and an inner region of the first reference mark 56 surrounded by the region in ring shape in the plan view. In other words, an entirety of the inner region surrounded by a periphery of the first reference mark 56 can be referred to as a region overlapping the first reference mark 56. In the method above, the first determination pattern 59 is formed in a region spaced inward from the first reference mark 56. The first determination pattern 59 can be in island shape in the plan view.

The first determination pattern 59 can be used to determine whether the first resist film 55 is positional deviated with respect to the first wiring layer 43 just formed previously. For example, as shown in FIG. 5A, if a distance L1 from a center C1 of the first determination pattern 59 to a center of the first reference mark 56 in ring shape in a widthwise direction is substantially constant throughout a peripheral direction of the first reference mark 56, it can be determined that there is no positional deviation.

The first peripheral pattern 60 is in ring shape greater than the first reference mark 56 in the plan view, and surrounds the first reference mark 56. The second peripheral pattern 61 is in ring shape greater than the first peripheral pattern 60 in the plan view, and further surrounds the first peripheral pattern 60.

The first peripheral pattern 60 and the second peripheral pattern 61 are auxiliary opening patterns for suppressing light interference generated due to influences of the multiple element regions 6 around the cutting predetermined lines 7. In each of the element regions 6 around the cutting predetermined lines 7, in addition to the CMOS transistor 9 shown in FIG. 3, multiple functional elements are also formed. Thus, when the first determination pattern 59 is formed in the determination mark region 8, light interference caused by influences of the element structure 54 in the element region 6 can degrade the patterning precision of the first determination pattern 59.

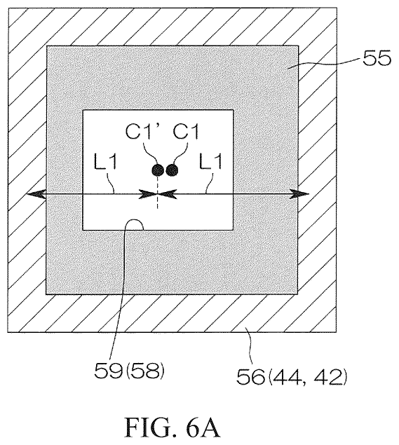

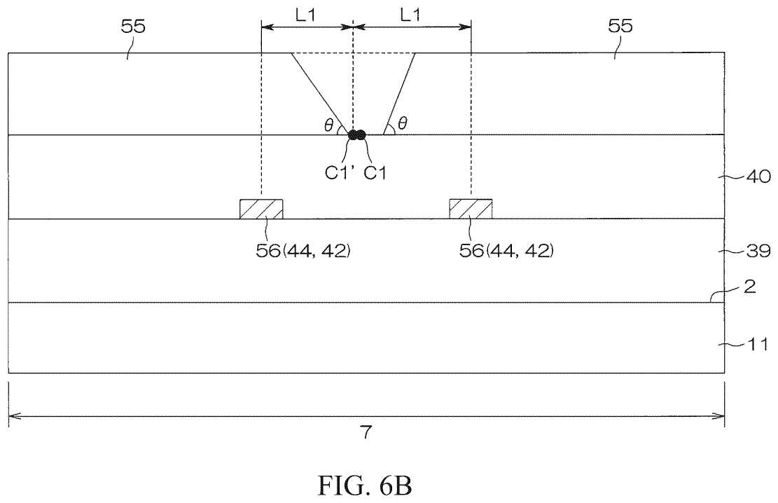

For example, as shown in FIG. 6A and FIG. 6B, in an aspect where only the first determination pattern 59 is formed as the first outer opening 58, since the precision of the exposure process is degraded by interference from ambient light in the surroundings, a deviation in a taper angle θ of a sidewall of the first determination pattern 59 is resulted. Thus, there is a concern that, by erroneously identifying an image at a position deviated from the actual center C1 of the first determination pattern 59 as a center C1′, positional deviation is determined to be present. In particular, when the thickness of the first resist film 55 is relatively large such as between about 35000 Å and about 40000 Å, the deviation in the taper angle θ becomes significant.

With respect to the above, as shown in FIG. 5A and FIG. 5B, if the first peripheral pattern 60 and the second peripheral pattern 61 surrounding the first determination pattern 59 are formed, light interference caused by influences of the element structure 54 of the element region 6 can be suppressed. Accordingly, the taper angle θ in the first determination pattern 59 is set to be constant. As a result, the precision of positional deviation determination can be improved. Alternatively, only either one of the first peripheral pattern 60 and the second peripheral pattern 61 is used. However, by surrounding the first determination pattern 59 in a dual manner, the precision of positional deviation determination can be further improved.

Next, referring to FIG. 4H, the second conductive layer 46 is formed on the second insulating layer 40. For example, by means of sputtering, a conductive material is deposited on the second insulating layer 40 across from the first resist film 55. Accordingly, the second conductive layer 46 including the conductive material deposited inside the first element-side opening 57 and the first outer opening 58 is formed. The second conductive layer 46 includes the second wiring layer 47 as an example of a second element pattern on the side of the element region 6 and the second outer layer 48 on the side of the cutting predetermined line 7. Next, referring to FIG. 4I, the first resist film 55 is removed.

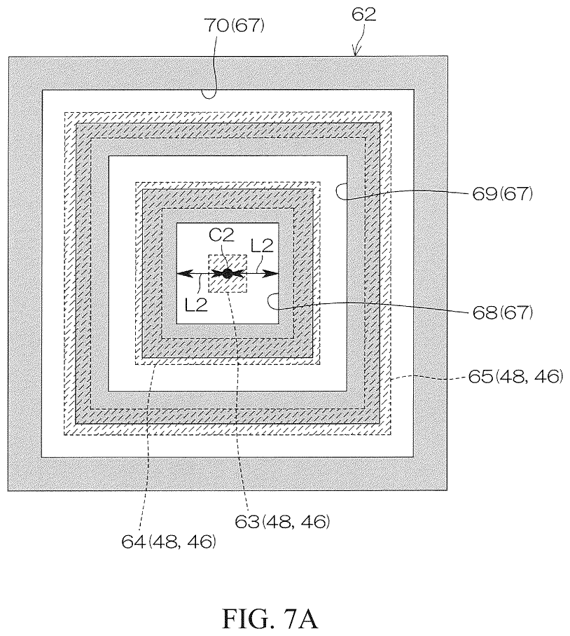

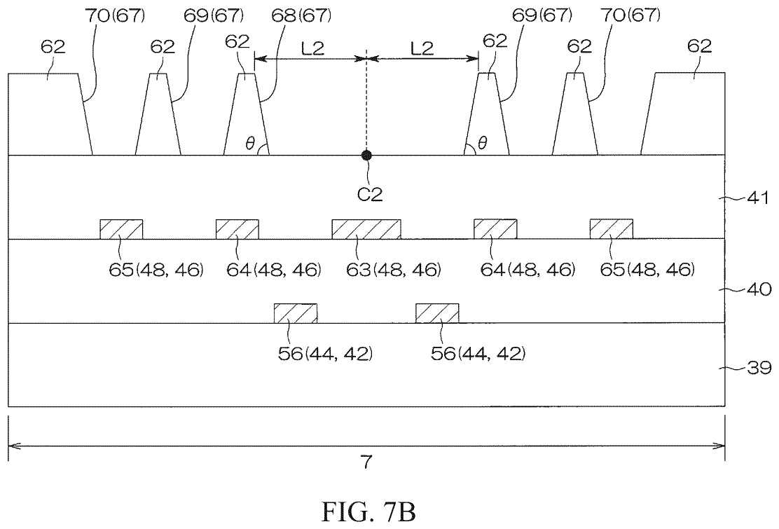

Referring to FIG. 7A and FIG. 7B, processes for forming the second conductive layer 46 are to be described in detail herein. FIG. 7A and FIG. 7B are respectively diagrams of a planar pattern and a section pattern of the second resist film 62. FIG. 7B shows an enlarged structural diagram of the cutting predetermined line 7.

Referring to FIG. 7A and FIG. 7B, the second outer layer 48 includes a second reference mark 63, a first peripheral mark 64 and a second peripheral mark 65. The second reference mark 63 can be consistent with the planar shape of the first determination pattern 59, or can be in island shape in the plan view. The first peripheral mark 64 is substantially consistent with the planar shape of the first peripheral pattern 60, is in ring shape greater than the second reference mark 63 in the plan view, and surrounds the second reference mark 63. The second peripheral mark 65 is substantially consistent with the planar shape of the second peripheral pattern 61, is in ring shape greater than the first peripheral mark 64 in the plan view, and surrounds the first peripheral mark 64.

Referring to FIG. 4J, the third insulating layer 41 is formed on the second insulating layer 40 to cover the second conductive layer 46. The third insulating layer 41 can be formed by means of CVD, for example.

Next, referring to FIG. 4K, the third channel electrode 53 is embedded into the third insulating layer 41. For example, multiple channel holes are selectively formed in the third insulating layer 41, and the channel holes are filled by a conductive material to accordingly form the third channel electrode 53. The third channel electrode 53 can be formed of tungsten (W), for example.

Next, referring to FIG. 4L, the second resist film 62 is formed on the third insulating layer 41. The second resist film 62 indirectly covers the second wiring layer 47 and the second outer layer 48 across from the third insulating layer 41. The second resist film 62 can be a commonly known resist (in either a positive or negative type). The thickness of the second resist film 62 is, for example, between about 35000 Å and about 40000 Å. For example, the material of the second resist film 62 is applied onto an entire surface of the third insulating layer 41 and then pre-baked, and the resist material is exposed. The resist material having been exposed is developed to obtain the second resist film 62. After the developing, a cleansing (cleaning) process and a post-baking process can be performed as needed.

The second resist film 62 having been developed includes a second element-side opening 66 and a second outer opening 67. The second element-side opening 66 is consistent with a pattern of the third wiring layer 51. The second outer opening 67 is consistent with a pattern of the third outer layer 52.

Referring to FIG. 7A and FIG. 7B, the second outer opening 67 is described in detail herein. In FIG. 7A, the part of an opening of the second resist film 62 is indicated as unshaded, and the part of a film of the second resist film 62 is indicated as shaded. The second outer opening 67 includes a second determination pattern 68, a first peripheral pattern 69 and a second peripheral pattern 70.

The second determination pattern 68 forms a region overlapping the second reference mark 63 in the plan view. In the method above, the second determination pattern 68 is formed to cover an entirety of the second reference mark 63. The second determination pattern 68 can be in island shape greater than the second reference mark 63 in the plan view.

The second determination pattern 68 can be used to determine whether the second resist film 62 is positional deviated with respect to the second wiring layer 47 just formed previously. For example, as shown in FIG. 7A, if a distance L2 from a center C2 of the second reference mark 63 to a sidewall of the second determination pattern 68 is substantially constant throughout a peripheral direction of the second determination pattern 68, it can be determined that there is no positional deviation.

The first peripheral pattern 69 is in ring shape greater than the second reference mark 63 in the plan view, and surrounds the second reference mark 63. The second peripheral pattern 70 is in ring shape greater than the first peripheral pattern 69 in the plan view, and further surrounds the first peripheral pattern 69.

The first peripheral pattern 69 and the second peripheral pattern 70, similar to the first peripheral pattern 60 and the second peripheral pattern 61 of the first resist film 55, are auxiliary opening patterns for suppressing light interference generated due to influences of the multiple element regions 6 around the cutting predetermined lines 7.

Thus, if the first peripheral pattern 69 and the second peripheral pattern 70 surrounding the second determination pattern 68 are formed, light interference caused by influences of the element structure 54 of the element region 6 can be suppressed. Accordingly, a taper angle θ in the second determination pattern 68 can be set to be constant. As a result, the precision of positional deviation determination can be improved. Alternatively, only either one of the first peripheral pattern 69 and the second peripheral pattern 70 is used. However, by surrounding the second determination pattern 68 in a dual manner, the precision of positional deviation determination can be further improved.

Next, referring to FIG. 4M, the third conductive layer 50 is formed on the third insulating layer 41. For example, by means of sputtering, a conductive material is deposited on the third insulating layer 41 across from the second resist film 62. Accordingly, the third conductive layer 50 including the conductive material deposited inside the second element-side opening 66 and the second outer opening 67 is formed. The third conductive layer 50 includes a third wiring layer 51 on the side of the element region 6 and a third outer layer 52 on the side of the cutting predetermined line 7. Next, referring to FIG. 4N, the first second film 62 is removed.

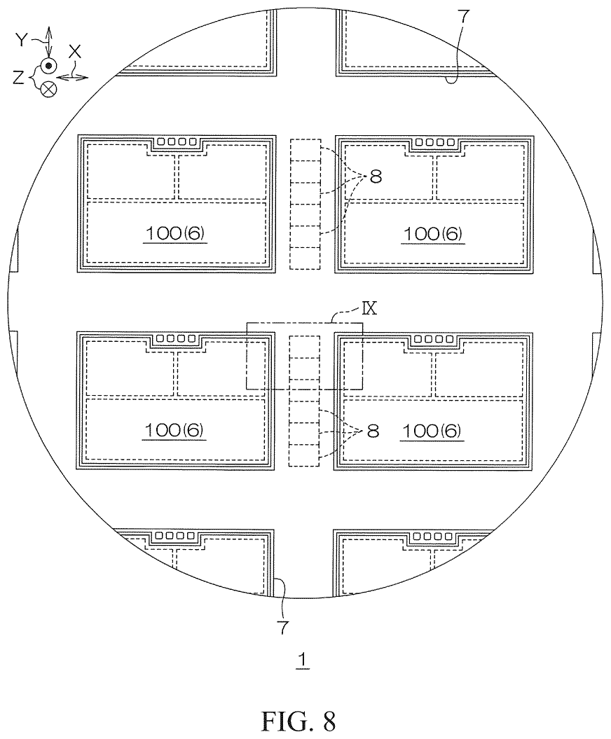

Next, referring to FIG. 4O, a surface insulating film 71 is formed on the third insulating layer 41 to cover the third conductive layer 50. The surface insulating film 71 can be formed by means of CVD, for example. The surface insulating film 71 can be, for example, a SiO₂ film or a SiN film. Then, a pad 72 for external connection is formed in each element region 6 by selectively forming an opening on the surface insulating film 71. FIG. 8 depicts a state of the first wafer main surface 2 of the wafer 1 after the pad 72 is formed.

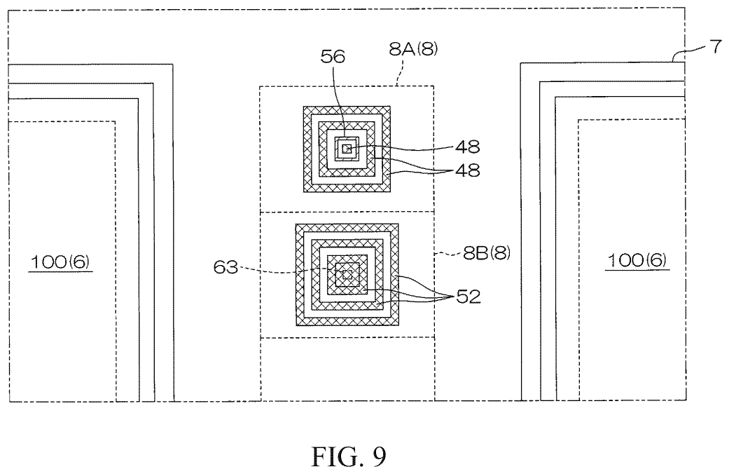

FIG. 8 shows an enlarged diagram of a main part of the wafer 1 (a wafer device 200) after the element structure 54 is formed. FIG. 9 shows an enlarged diagram of the part surrounded by the doubled-dotted line IX in FIG. 8.

Referring to FIG. 8 and FIG. 9, the wafer device 200 is the wafer 1 in which the element structure 54 is formed in each element region 6. The wafer device 200 can be the wafer 1 after the element structures 54 are formed and before the cutting predetermined lines 7 are cut. In the wafer device 200, the semiconductor device 100 having the same element structure 54 is formed in each element region 6. A reference mark for positional deviation determination of each of the resist films remains in the determination mark region 8 between adjacent semiconductor devices 100 (the element regions 6).

In FIG. 9, in an uppermost determination mark region 8A, the first reference mark 56 for determination positional deviation of the first resist film 55, and the second outer layer 48 deposited and formed inside the first outer opening 58 of the first resist film 55 remain. Moreover, in a determination mark region 8B adjacently below the determination mark region 8A, the second reference mark 63 for determination positional deviation of the second resist film 62, and the third outer layer 52 deposited and formed inside the second outer opening 67 of the second resist film 62 remain.

Next, referring to FIG. 4P, the wafer 1 (the wafer device 200) is cut along the cutting predetermined line 7. With the processes described above, multiple semiconductor devices 100 are made from one piece of wafer 1.

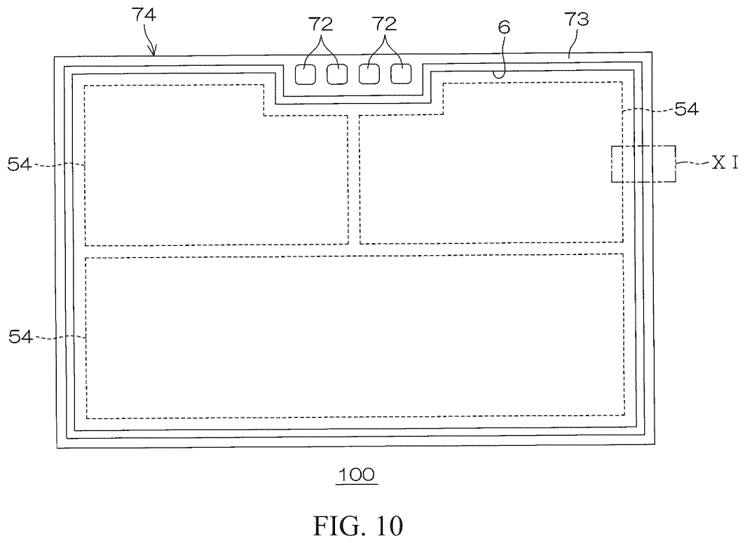

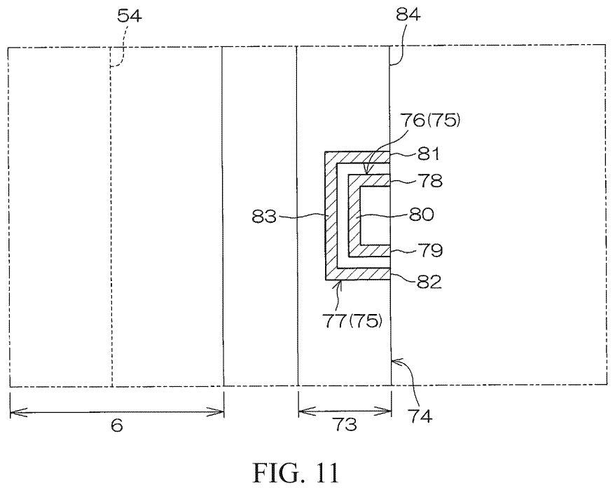

FIG. 10 shows a schematic plan view of the semiconductor device 100. FIG. 11 shows an enlarged diagram of the part surrounded by the doubled-dotted line XI in FIG. 10.

Referring to FIG. 10 and FIG. 11, the semiconductor device 100 includes a chip 74 including the element regions 6 and peripheral regions 73, multiple element structures 54 formed in the element regions 6, and pads 72 electrically connected to the element structures 54. The chip 74 is formed by the substrate 10 and the epitaxial layer 11. The peripheral region 73 surrounding the element regions 6 is a residual portion of the cutting predetermined lines 7.

In the peripheral region 73, a portion of the second outer layer 48 that is left behind when the wafer 1 is cut is used as a peripheral pattern 75. For example, as shown in FIG. 11, the peripheral pattern 75 is in ring shape having ends. In the method above, the peripheral pattern 75 includes a first peripheral pattern 76, and a second peripheral pattern 77 surrounding the first peripheral pattern 76.

One end 78 and the other end 79 of the first peripheral pattern 76 are exposed to an exterior from a same end face 84 of the chip 74, and a middle portion 80 between the one end 78 and the other end 79 is disposed on an inside of the end face 84 of the chip 74. Similarly, an end 81 and the other end 82 of the second peripheral pattern 77 are exposed to an exterior from the same end face 84 of the chip 74, and a middle portion 83 between the one end 81 and the other end 82 is disposed on an inside of the end face 84 of the chip 74.

Moreover, in FIG. 11, although only the second outer layer 48 is depicted, a portion of the third outer layer 52 similarly remains in the in the peripheral region 73.

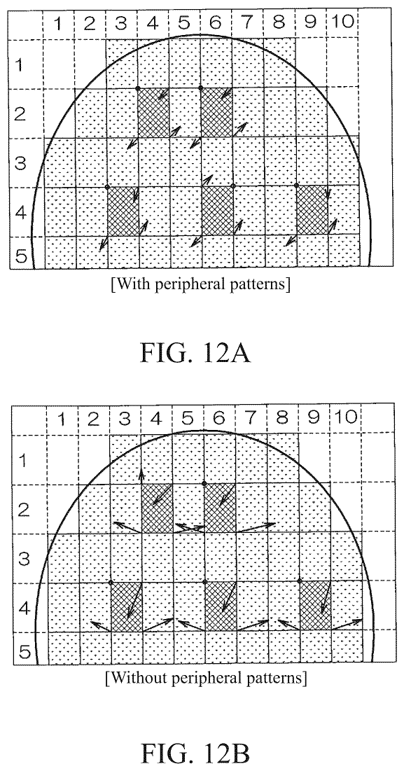

FIG. 12A and FIG. 12B are diagrams of measurement results of a positional deviation of a resist film in sample 1. In FIG. 12A and FIG. 12B, each of the quadrilaterals represents a region in which one-shot exposure is performed by an exposure device (a stepper machine).

In sample 1 in FIG. 12A, in simulation to FIG. 5A and FIG. 5B, for positional deviation determination, a resist forming the first determination pattern 59 and the first peripheral pattern 60 surrounding the first determination pattern 59 is used. In sample 2 in FIG. 12A, in simulation to FIG. 6A and FIG. 6B, for positional deviation determination, a resist forming only the first determination pattern 59 is used.

Between FIG. 12A and FIG. 12B, the positional deviation in the regions indicated by intersecting shading lines is compared. The amounts and directions of the positional deviation are represented by arrows extending from the individual regions. The amount of positional deviation is larger as an arrow gets longer. More specifically, a residual error in the each region is measured, and the measured result is represented by the arrow of each region. Moreover, by comparing the lengths of the arrows in FIG. 12A and FIG. 12B, it is determined the position in which region has a greater amount of deviation. Herein, the term “residual error” can signify, apart from displacement deviation, rotational deviation and magnification deviation, an amount of deviation that cannot be further corrected.

It is seen from FIG. 12A and FIG. 12B that, sample 1 having the first peripheral pattern 60 formed therein has a smaller residual error compared to sample 2. As an example, with the configuration of sample 1, the residual error in sample 2 can be alleviated to about ⅓ for a certain region.

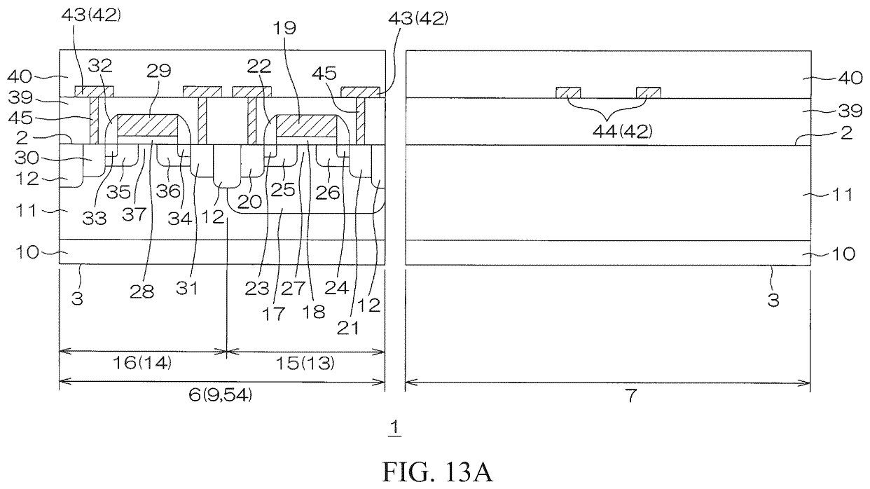

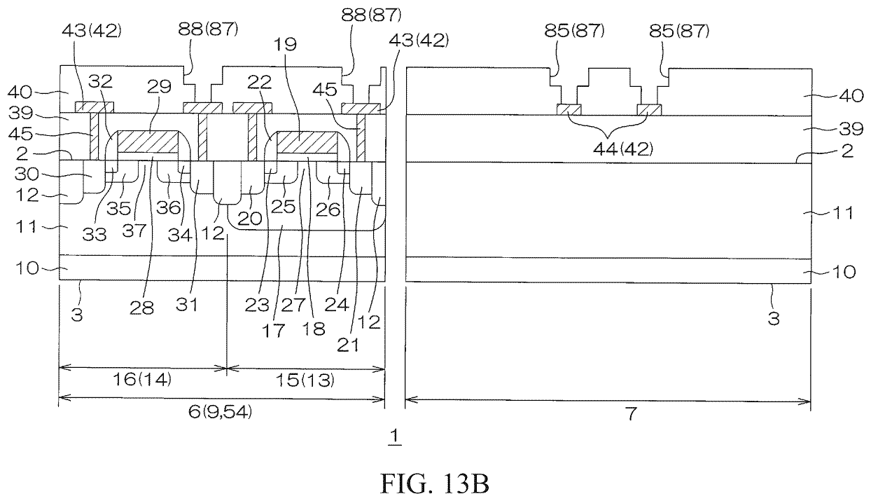

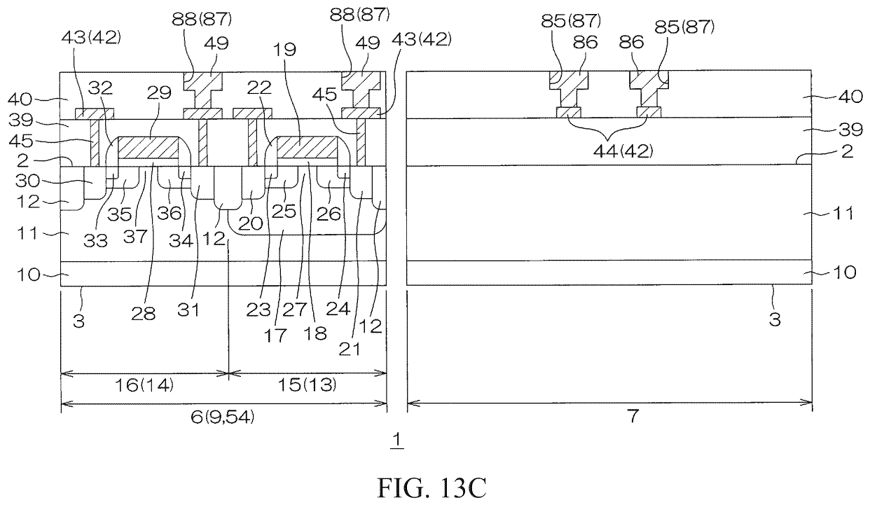

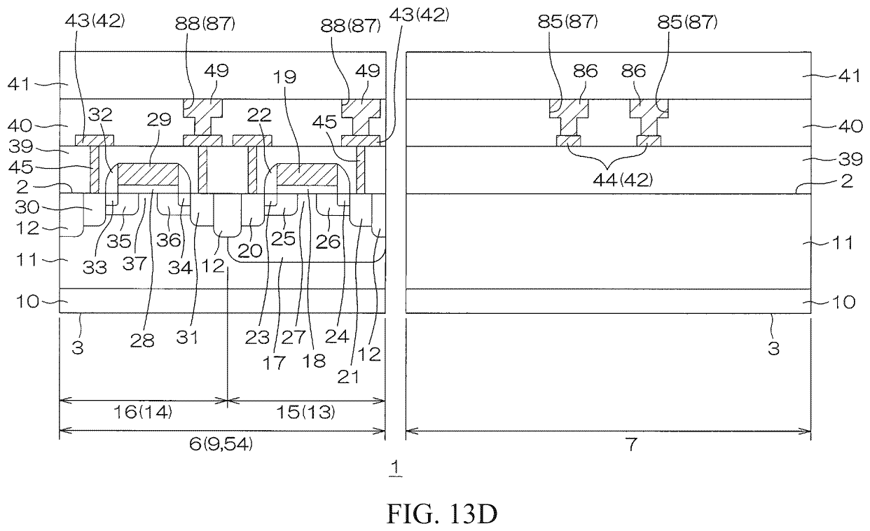

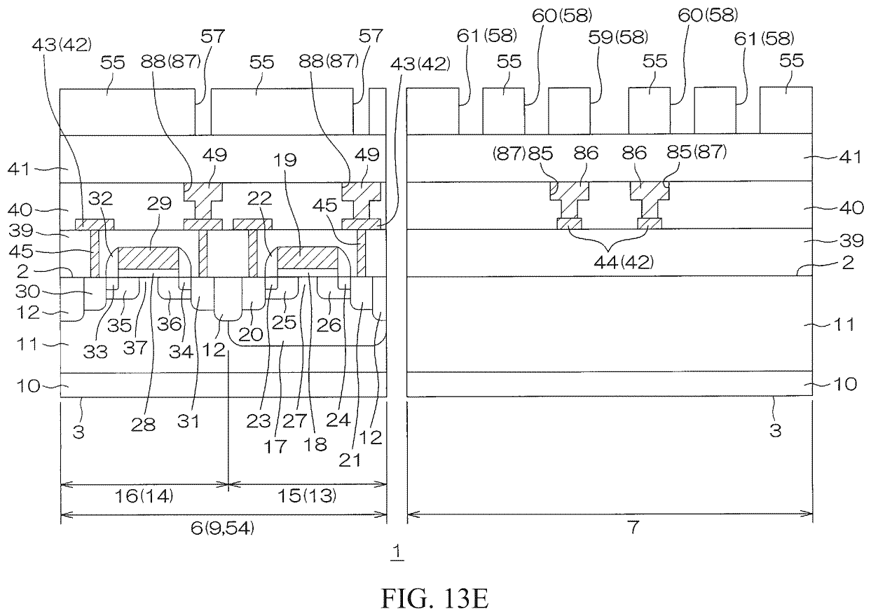

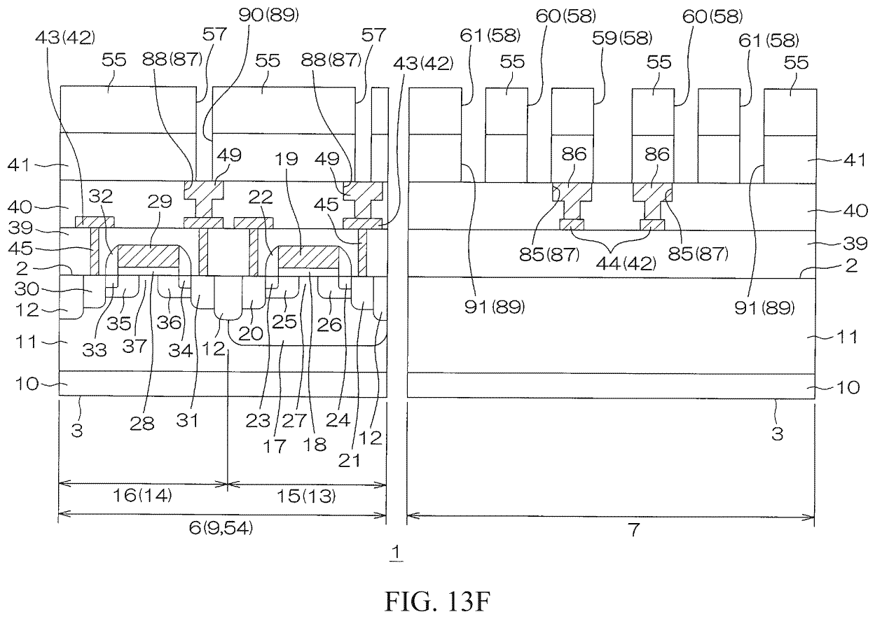

Next, referring to FIG. 13A to FIG. 13B, other approaches of examples of a method for manufacturing the semiconductor device 100 are described. In FIG. 13A to FIG. 13F, structures the same as the structures in FIG. 4A to FIG. 4P are denoted by the same symbols or numerals, and the associated description is omitted. The processes in FIG. 13A to FIG. 13F primarily differ from the processes in FIG. 4A to FIG. 4P in that, in the processes in FIG. 13A to FIG. 13F, a first reference mark opening 85 and a second reference mark embedding layer 86 formed in the second insulating layer 40 are used as reference marks for positional deviation determination of the first resist film 55.

More specifically, first of all, referring to FIG. 13A, processes the same as the processes of FIG. 4A to FIG. 4E are performed. Next, referring to FIG. 13B, a first opening 87 as an example of a first layer is formed in the second insulating layer 40. The first opening 87 includes a first contact opening 88 on the side of the element region 6, and the first reference mark opening 85 on the side of the cutting predetermined line 7. The first opening 87 is formed by selectively etching the second insulating layer 40. The first wiring layer 43 is exposed from the first contact opening 88, and the first outer layer 44 is exposed from the first reference mark opening 85. The same as the first reference mark 56, the first reference mark opening 85 can be in ring shape in the plan view (referring to FIG. 5A).

Next, referring to FIG. 13C, a conductive material is embedded into the first contact opening 88 and the first reference mark opening 85 by depositing the conductive material on the second insulating layer 40. Accordingly, the second channel electrode 49 embedded into the first contact opening 88 and the first reference mark embedding layer 86 embedded into the first reference mark opening 85 can be obtained. The first reference mark embedding layer 86, since being embedded into the first reference mark opening 85, is formed in ring shape in the plan view.

Referring to FIG. 13D, the third insulating layer 41 is formed on the second insulating layer 40 to cover the second channel electrode 49 and the first reference mark embedding layer 86. The third insulating layer 41 can also be formed by means of CVD, for example.

Next, referring to FIG. 13E, the first resist film 55 is formed on the third insulating layer 41. The first resist film 55 indirectly covers the second channel electrode 49 and the first reference mark embedding layer 86 across from the third insulating layer 41. The first resist film 55 is similarly formed, exposed and developed as the process in FIG. 4G. The first resist film 55 having been developed includes a first element-side opening 57 and a first outer opening 58.

In the process in FIG. 13E, the same as the first resist film 55 shown in FIG. 5A and FIG. 5B, the first outer opening 58 includes the first determination pattern 59, the first peripheral pattern 60 and the second peripheral pattern 61. The positional deviation of the first resist film 55 can be determined based on a positional relation between the first determination pattern 59 and the first reference mark embedding layer 86. Moreover, with the first peripheral pattern 60 and the second peripheral pattern 61 formed to surround the first reference mark embedding layer 86, the precision of positional deviation can be improved.

Next, referring to FIG. 13F, a second opening 89 is formed by selectively etching the third insulating layer 41 across from the first resist film 55. The second opening 89 includes a second contact opening 90 on the side of the element region 6, and a second reference mark opening 91 on the side of the cutting predetermined line 7. The second contact opening 90 is an opening for the third channel electrode 53. The second reference mark opening 91 corresponds an opening for the second reference mark 63, the first peripheral mark 64 and the second peripheral mark 65 in FIG. 7A and FIG. 7B. Then, with the processes the same as those in FIG. 4H to FIG. 4P, the semiconductor devices 100 can be obtained.

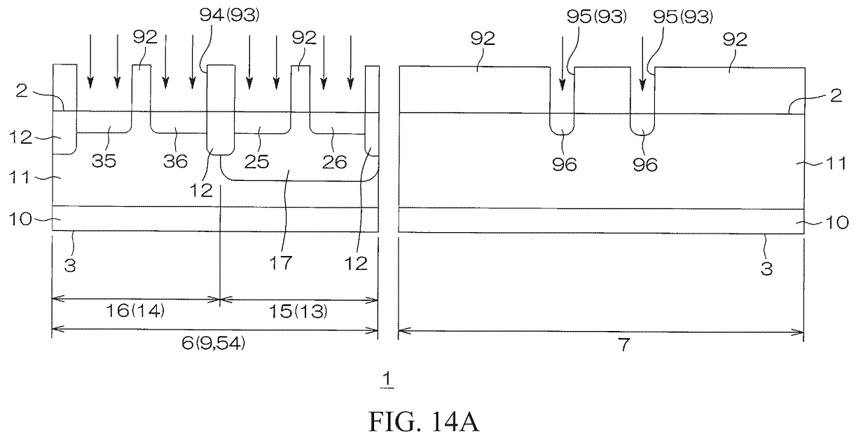

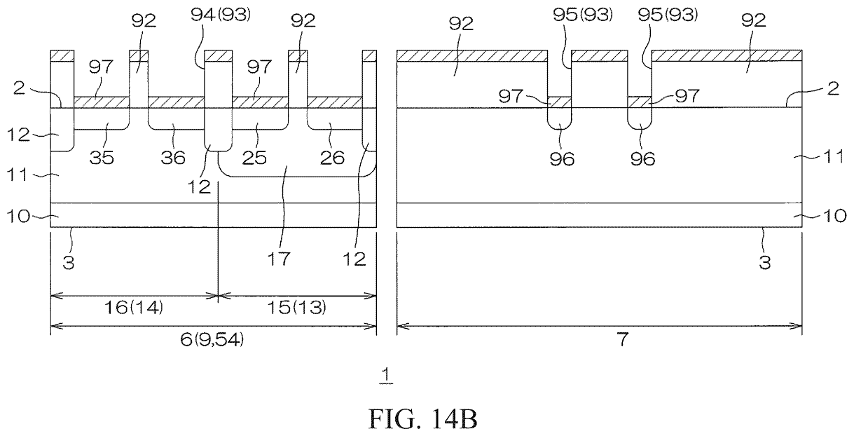

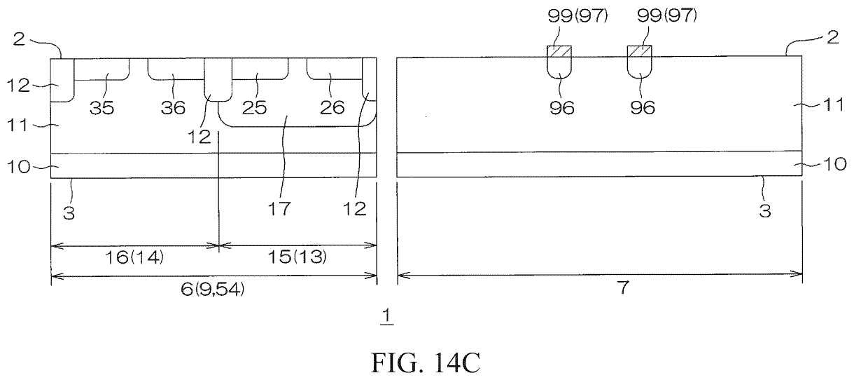

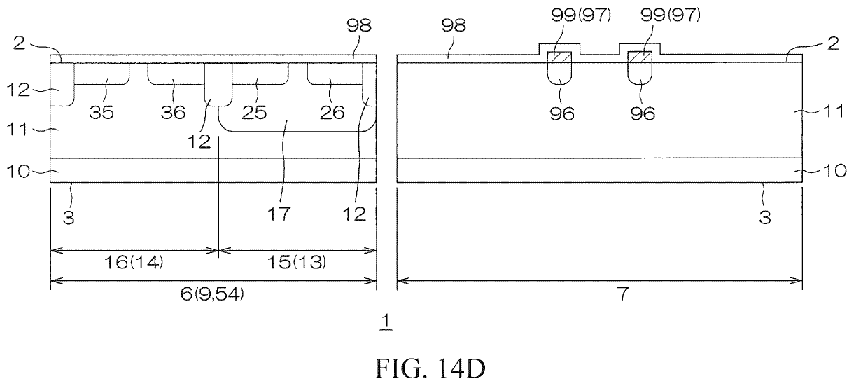

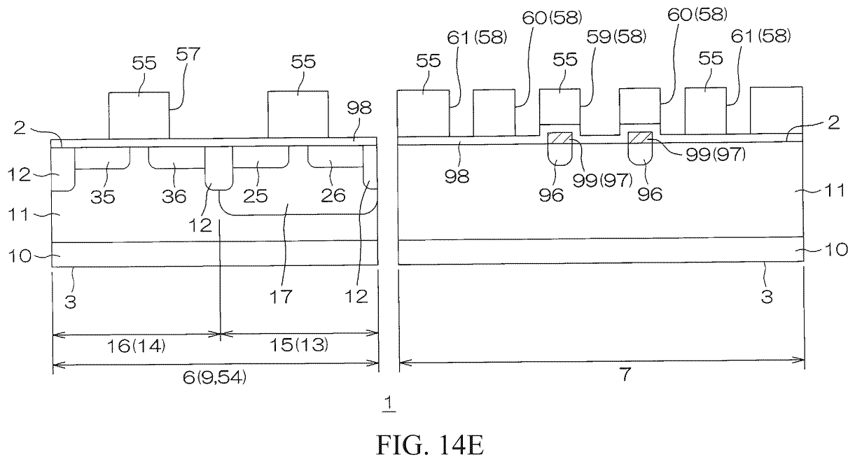

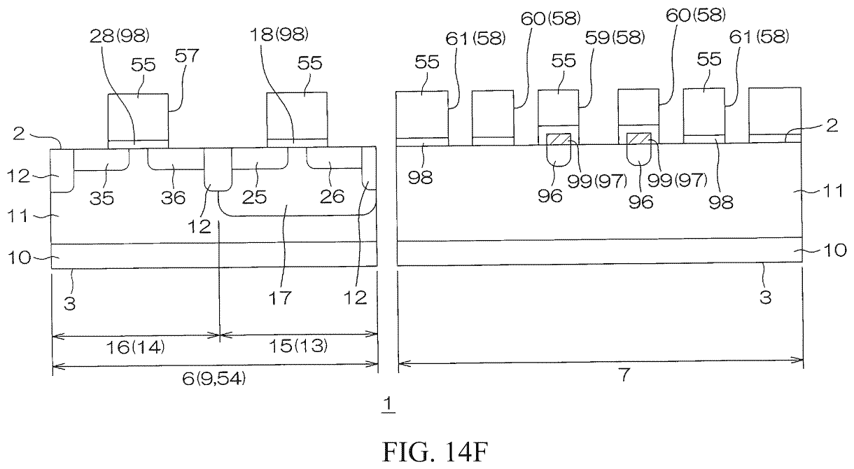

Next, referring to FIG. 14A to FIG. 14F, other approaches of examples of a method for manufacturing the semiconductor device 100 are described. In FIG. 14A to FIG. 14F, structures the same as the structures in FIG. 4A to FIG. 4P are denoted by the same symbols or numerals, and the associated description is omitted. The processes in FIG. 14A to FIG. 14F primarily differ from the processes in FIG. 4A to FIG. 4P in that, in the processes in FIG. 14A to FIG. 14F, positional deviation determination of the first resist film 55 is not performed while wirings are formed, but is performed while impurity regions and gate structures are formed.

More specifically, referring to FIG. 14A, after the element separating portion 12 and the p-type well 17 are formed in the element region 6 of the wafer 1, an impurity is selectively injected to the first wafer main surface 2 across from a resist film 92. The resist film 92 has an opening 93 selectively exposing the first wafer main surface 2. The opening 93 includes an element-side opening 94 on the side of the element region 6, and an outer opening 95 on the side of the cutting predetermined line 7.

By injecting the impurity from the element-side opening 94, the p-type source sac-like implantation region 25, the p-type drain sac-like implantation region, the n-type source sac-like implantation region 35 and the n-type drain source sac-like implantation region 36 having predetermined patterns are formed on the first wafer main surface 2. On the other hand, by injecting the impurity from the outer opening 95, a reference mark impurity region 96 having a predetermined pattern is formed on the first wafer main surface 2. The same as the first reference mark 56, the reference mark impurity region 96 can be in ring shape in the plan view (referring to FIG. 5A).

Next, referring to FIG. 14B, a reference conductive layer 97 as an example of the first layer is formed on the first wafer main surface 2. For example, by means of sputtering, a conductive material is deposited on the first wafer main surface 2 across from the resist film 92. Accordingly, the reference conductive layer 97 including the conductive material deposited inside the element-side opening 94 and the outer opening 95 is formed. The reference conductive layer 97 of the element-side opening 94 is formed in ring shape in the plan view.

Next, referring to FIG. 14C, the resist film 92 is removed, and then the reference conductive layer 97 on the side of the element region 6 is removed. Accordingly, the reference conductive layer 97 used as a reference mark 99 selectively remains at the cutting predetermined line 7.

Next, referring to FIG. 14D, a substrate insulating film 98 is formed on the first wafer main surface 2 to cover the reference conductive layer 97. The substrate insulating layer 98 is a film of a base material that is to become the p-side gate insulating film 28 and the n-side gate insulating film 18.

Next, referring to FIG. 14E, the first resist film 55 is formed on the substrate insulating film 98. The first resist film 55 indirectly covers the reference mark 99 across from the substrate insulating film 98. The first resist film 55 is similarly formed, exposed and developed as the process in FIG. 4G. The first resist film 55 having been developed includes a first element-side opening 57 and a first outer opening 58.

In the process in FIG. 14E, the same as the first resist film 55 shown in FIG. 5A and FIG. 5B, the first outer opening 58 includes the first determination pattern 59, the first peripheral pattern 60 and the second peripheral pattern 61. The positional deviation of the first resist film 55 can be determined based on a positional relation between the first determination pattern 59 and the reference mark 99. Moreover, with the first peripheral pattern 60 and the second peripheral pattern 61 formed to surround the first reference mark embedding layer 86, the precision of positional deviation can be improved.

Next, referring to FIG. 14F, the substrate insulating film 98 is selectively etched across from the first resist film 55 to form the p-side gate insulating film 28 and the n-side gate insulating film 18 in the element region 6. Then, after the element structure 54 including the CMIS transistor 9 is formed, by performing the processes the same as those in FIG. 4A to FIG. 4P, the semiconductor devices 100 can be obtained.

The embodiments of the present disclosure are as described above; however, the present disclosure can have other implementation forms.

For example, in the embodiments, the first resist film 55 includes the first determination pattern 59 as a positional deviation determination pattern, and includes the first peripheral pattern 60 and the second peripheral pattern 61 as auxiliary patterns for suppressing light interference. The first determination pattern 59, the first peripheral pattern 60 and the second peripheral pattern 61 are all opening patterns formed on the first resist film 55.

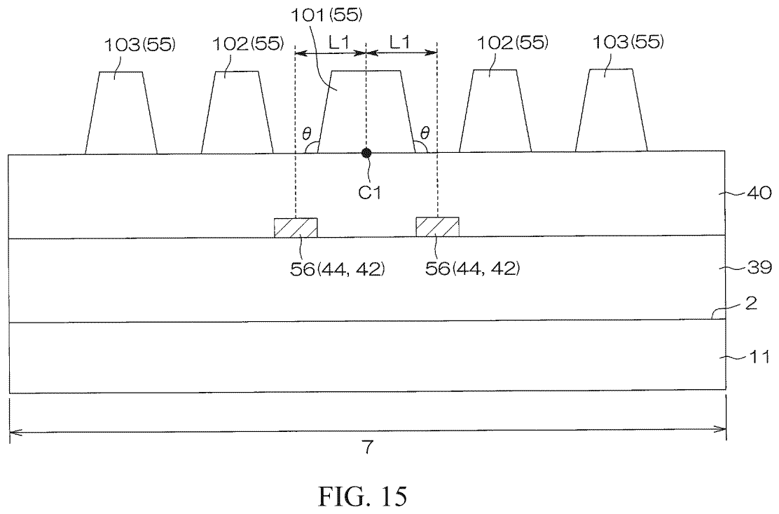

In contrast, as shown in FIG. 15, the first resist film 55 can also include mesa patterns as positional deviation determination patterns and auxiliary patterns. That is to say, the first resist film 55 can also have patterns opposite to the patterns in FIG. 5A and FIG. 5B. For example, the first resist film 55 can include a first determination mesa pattern 101 corresponding to the first determination pattern 59, a first peripheral mesa pattern 102 corresponding to the first peripheral pattern 60, and a second peripheral mesa pattern 103 corresponding to the second peripheral pattern 61. In this case, if a distance L1 from a center C1 of the first determination mesa pattern 101 to the center of the first reference mark 56 in ring shape in a widthwise direction is substantially constant throughout a peripheral direction of the first reference mark 56, it can be determined that there is no positional deviation.

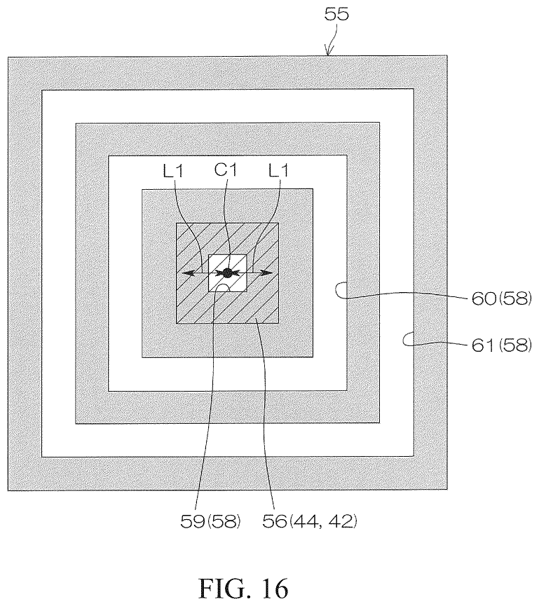

Moreover, in the embodiment above, the first reference mark 56 is in ring shape in the plan view, but can also be in island shape, as shown in FIG. 16.

Moreover, in the embodiments above, the positional deviation of the first resist film 55 is determined based on whether the distance L1 from the center C1 of the first determination pattern 59 to the center of the first reference mark 56 in ring shape in the widthwise direction is constant, but other methods can also be used for the determination. For example, the positional deviation can also be determined based on whether the center of the first determination pattern is consistent with the center of the first reference mark 56 (that is, an intersection point of a pair of diagonal lines).

Moreover, in the embodiments above, the auxiliary pattern for suppressing light interference is in a structure surrounded in a dual manner by the first peripheral pattern 60 and the second peripheral pattern 61, but a third peripheral pattern, a fourth peripheral pattern, . . . and an nth peripheral pattern can further be formed (where n is a natural number).

Moreover, in the embodiments above, only the CMIS transistor 9 is shown as an example of the element structure 54 formed at the wafer 1; however, the element structure 54 can also be implemented by various structures of various functional elements.

The embodiments of the present disclosure described above are examples in all aspects and are not to be interpreted in a restrictive manner, but are intended to encompass modifications in all aspects.

The features given in the note below can be extracted from the description and the drawings and the present detailed description.

### [Note 1-1]

A method for manufacturing a semiconductor device (100), comprising:
a first process of forming a first layer (39, 40, 99) on a main surface of a wafer (1), wherein the first layer has a reference mark (56) for measuring a positional deviation of a resist (55) relative to a first element pattern (25, 26, 35, 36, 43) for a semiconductor element (9, 54);
a second process of forming the resist (55) on the first layer (39, 40, 99) to cover the reference mark (56) and the first element pattern (25, 26, 35, 36, 43);
a third process of exposing and developing the resist (55) to form a positional deviation determination pattern (59, 101) overlapping the reference mark (56) in a plan view, a peripheral pattern (60, 61, 102, 103) surrounding the positional deviation determination pattern (59, 101) in the plan view, and a second element pattern (47) for the semiconductor element (9, 54); and a fourth process of determining a positional deviation of the second element pattern (47) with respect to the first element pattern (25, 26, 35, 36, 43) by measuring a relative position of the positional deviation determination pattern (59, 101) with respect to the reference mark (56).

According to the method, since the peripheral pattern (60, 61, 102, 103) surrounding the positional deviation determination pattern (59, 101) is formed outside the reference mark (56), light interference caused by influences of surrounding element structures can be suppressed. Accordingly, the precision of positional deviation determination with respect to the first element pattern (25, 26, 35, 36, 43) can be improved.

### [Note 1-2]

The method for manufacturing a semiconductor device (100) according to note 1-1, wherein in the third process, the resist (55) is configured to form a plurality of peripheral patterns (61, 103) including a first peripheral pattern (60, 102) surrounding the positional deviation determination pattern (59, 101), and a second peripheral pattern (61, 103) surrounding the first peripheral pattern (60, 102).

According to the method, the precision of positional deviation determination can be further improved by surrounding the positional deviation determination pattern (59, 101) in a dual manner at least by the first peripheral pattern (60, 102) and the second peripheral pattern (61, 103).

### [Note 1-3]

The method for manufacturing a semiconductor device (100) according to note 1-2, wherein the wafer (1) includes a plurality of element regions (6) in which the semiconductor element (9, 54) is formed, and a cutting region (7) dividing the plurality of element regions (6), and the reference mark (56) is formed in the cutting region (7).

### [Note 1-4]

The method for manufacturing a semiconductor device (100) according to note 1-2 or 1-3, wherein all of the positional deviation determination pattern (59), the first peripheral pattern (60) and the second peripheral pattern (61) are opening patterns formed in the resist (55).

### [Note 1-5]

The method for manufacturing a semiconductor device (100) according to note 1-2 or 1-3, wherein all of the positional deviation determination pattern (101), the first peripheral pattern (102) and the second peripheral pattern (103) are mesa patterns defined by opening patterns formed in the resist (55).

### [Note 1-6]

The method for manufacturing a semiconductor device (100) according to any one of notes 1-1 to 1-5, wherein the resist has a thickness between about 35,000 Å and about 40,000 Å.

### [Note 1-7]

The method for manufacturing a semiconductor device (100) according to any one of notes 1-1 to 1-6, wherein the first process includes:
a first step of forming an insulating layer (39) as the first layer (39) on the main surface of the wafer (1); and
a second step of forming an element wiring (43) corresponding to the first element pattern (43) and a reference mark conductive layer (56) corresponding to the reference mark (56) by selectively depositing a conductive material on the insulating layer (39).

### [Note 1-8]

The method for manufacturing a semiconductor device (100) according to any one of notes 1 to 1-7, wherein in the first process, the reference mark conductive layer (56) is formed in ring shape in the plan view, in the third process, the positional deviation determination pattern (59, 101) in island shape in the plan view is formed on a region surrounded by the reference mark conductive layer (56), and the peripheral pattern (60, 61, 102, 103) is formed in ring shape in the plan view and surrounds the reference mark conductive layer (56).

### [Note 1-9]

The method for manufacturing a semiconductor device (100) according to any one of notes 1-1 to 1-6, wherein the first process includes:
a first step of forming an insulating layer (40) as the first layer (40) on the main surface of the wafer (1);
a second step of selectively removing the insulating layer (40) to form an element wiring opening (88) corresponding to the first element pattern (43) and a reference mark opening (85) corresponding to the reference mark (56); and
a third step of embedding an element embedding wiring (49) in the element wiring opening (88) and embedding a reference mark embedding layer (86) in the reference mark opening (85).

### [Note 1-10]

The method for manufacturing a semiconductor device (100) according to note 1-9, wherein in the first process, the reference mark embedding layer (86) is formed in ring shape in the plan view, in the third process, the positional deviation determination pattern (59, 101) in island shape in the plan view is formed on a region surrounded by the reference mark embedding layer (86), and the peripheral pattern (60, 61, 102, 103) is formed in ring shape in the plan view and surrounds the reference mark embedding layer (86).

### [Note 1-11]

The method for manufacturing a semiconductor device (100) according to any one of notes 1-1 to 1-6, wherein the first process includes:
a first step of forming an element impurity region (25, 26, 3, 36) corresponding to the first element pattern (25, 26, 3, 36) and an impurity region (96) for the reference mark (99) by selectively injecting an impurity into the main surface of the wafer (1); and
a second step of forming the reference mark (99) by selectively leaving the first layer (99) on the impurity region (96) for the reference mark (99) of the main surface of the wafer (1).

### [Note 1-12]

The method for manufacturing a semiconductor device (100) according to note 1-11, wherein in the first process, the reference mark (99) is formed in ring shape in the plan view, in the third process, the positional deviation determination pattern (59, 101) in island shape in the plan view is formed on a region surrounded by the reference mark (99), and the peripheral pattern (60, 61, 102, 103) is formed in ring shape in the plan view and surrounds the reference mark (99).

### [Note 1-13]

A semiconductor wafer (200), comprising:
a wafer body (1), having a plurality of element regions (6) and a cutting predetermined region (7) for dividing the plurality of element regions (6);
a first element pattern (43), formed in each of the plurality of element regions (6); an outer mark (56), formed in the cutting predetermined region (7) and in same layer as the first element pattern (43);
a second element pattern (47), formed in an upper region of the first element pattern (43); and
an outer pattern (63) and a peripheral pattern (64, 65), formed in same layer as the second element pattern (47) and in the cutting predetermined region (7), wherein the outer pattern (63) overlaps with the outer mark (65) in a plan view, and the peripheral pattern (64, 65) surrounds the outer mark in the plan view.

### [Note 1-14]

A semiconductor device (100), comprising:
a chip (74), having an element region (6) and a peripheral region (73);
an element pattern (47), formed in the element region (6); and a peripheral pattern (75, 76, 77), formed in the peripheral region (73) in same layer as the element pattern (47) and formed in a ring having ends in a plan view,
wherein one end (78, 81) and another end (79, 82) of the ring having ends of the peripheral pattern (75, 76, 77) are exposed to an exterior side from a same end face (84) of the chip, and a portion (80, 83) between the one end (78, 81) and the another end (79, 82) is disposed at an interior side of the end face (84) of the chip (74).

### [Note 1-15]

The semiconductor device (100) according to note 1-14, wherein the peripheral pattern (75, 76, 77) includes a first peripheral pattern (76) and a second peripheral pattern (77) surrounding the first peripheral pattern (76).

1. A method for manufacturing a semiconductor device, comprising:
a first process of forming a first layer on a main surface of a wafer, wherein the first layer has a reference mark for measuring a positional deviation of a resist relative to a first element pattern for a semiconductor element;
a second process of forming the resist on the first layer to cover the reference mark and the first element pattern;
a third process of exposing and developing the resist to form
a positional deviation determination pattern overlapping the reference mark in a plan view;
a peripheral pattern surrounding the positional deviation determination pattern in the plan view; and
a second element pattern for the semiconductor element; and
a fourth process of determining a positional deviation of the second element pattern with respect to the first element pattern by measuring a relative position of the positional deviation determination pattern with respect to the reference mark.

2. The method for manufacturing the semiconductor device of claim 1, wherein in the third process, the resist is configured to form a plurality of peripheral patterns including:
a first peripheral pattern surrounding the positional deviation determination pattern; and
a second peripheral pattern surrounding the first peripheral pattern.

3. The method for manufacturing the semiconductor device of claim 2, wherein
the wafer includes a plurality of element regions in which the semiconductor element is formed, and a cutting region dividing the plurality of element regions, and
the reference mark is formed in the cutting region.

4. The method for manufacturing the semiconductor device of claim 2, wherein all of the positional deviation determination pattern, the first peripheral pattern and the second peripheral pattern are opening patterns formed in the resist.

5. The method for manufacturing the semiconductor device of claim 2, wherein all of the positional deviation determination pattern, the first peripheral pattern, and the second peripheral pattern are mesa patterns defined by opening patterns formed in the resist.

6. The method for manufacturing the semiconductor device of claim 2, wherein the resist has a thickness between about 35,000 Å and about 40,000 Å.

7. The method for manufacturing the semiconductor device of claim 1, wherein the first process includes:
a first step of forming an insulating layer as the first layer on the main surface of the wafer; and
a second step of forming an element wiring corresponding to the first element pattern and a reference mark conductive layer corresponding to the reference mark by selectively depositing a conductive material on the insulating layer.

8. The method for manufacturing the semiconductor device of claim 2, wherein the first process includes:
a first step of forming an insulating layer as the first layer on the main surface of the wafer; and
a second step of forming an element wiring corresponding to the first element pattern and a reference mark conductive layer corresponding to the reference mark by selectively depositing a conductive material on the insulating layer.

9. The method for manufacturing the semiconductor device of claim 3, wherein the first process includes:
a first step of forming an insulating layer as the first layer on the main surface of the wafer; and
a second step of forming an element wiring corresponding to the first element pattern and a reference mark conductive layer corresponding to the reference mark by selectively depositing a conductive material on the insulating layer.

10. The method for manufacturing the semiconductor device of claim 7, wherein in the first process, the reference mark conductive layer is formed in ring shape in the plan view,
in the third process, the positional deviation determination pattern in island shape in the plan view is formed on a region surrounded by the reference mark conductive layer, and
the peripheral pattern is formed in ring shape in the plan view and surrounds the reference mark conductive layer.

11. The method for manufacturing the semiconductor device of claim 1, wherein the first process includes:
a first step of forming an insulating layer as the first layer on a main surface of the wafer;
a second step of selectively removing the insulating layer to form an element wiring opening corresponding to the first element pattern and a reference mark opening corresponding to the reference mark; and
a third step of embedding an element embedding wiring in the element wiring opening and embedding a reference mark embedding layer in the reference mark opening.

12. The method for manufacturing the semiconductor device of claim 2, wherein the first process includes:
a first step of forming an insulating layer as the first layer on a main surface of the wafer;
a second step of selectively removing the insulating layer to form an element wiring opening corresponding to the first element pattern and a reference mark opening corresponding to the reference mark; and
a third step of embedding an element embedding wiring in the element wiring opening and embedding a reference mark embedding layer in the reference mark opening.

13. The method for manufacturing the semiconductor device of claim 3, wherein the first process includes:
a first step of forming an insulating layer as the first layer on a main surface of the wafer;
a second step of selectively removing the insulating layer to form an element wiring opening corresponding to the first element pattern and a reference mark opening corresponding to the reference mark; and
a third step of embedding an element embedding wiring in the element wiring opening and embedding a reference mark embedding layer in the reference mark opening.

14. The method for manufacturing the semiconductor device of claim 11, wherein in the first process, the reference mark embedding layer is formed in ring shape in the plan view,
in the third process, the positional deviation determination pattern in island shape in the plan view is formed on a region surrounded by the reference mark embedding layer, and
the peripheral pattern is formed in ring shape in the plan view and surrounds the reference mark embedding layer.

15. The method for manufacturing the semiconductor device of claim 1, wherein the first process includes:
a first step of forming an element impurity region corresponding to the first element pattern and an impurity region for the reference mark by selectively injecting an impurity into the main surface of the wafer; and
a second step of forming the reference mark by selectively leaving the first layer on the impurity region for the reference mark of the main surface of the wafer.

16. The method for manufacturing the semiconductor device of claim 2, wherein the first process includes:
a first step of forming an element impurity region corresponding to the first element pattern and an impurity region for the reference mark by selectively injecting an impurity into the main surface of the wafer; and
a second step of forming the reference mark by selectively leaving the first layer on the impurity region for the reference mark of the main surface of the wafer.

17. The method for manufacturing the semiconductor device of claim 15, wherein
in the first process, the reference mark is formed in ring shape in the plan view,
in the third process, the positional deviation determination pattern in island shape in the plan view is formed in a region surrounded by the reference mark, and
the peripheral pattern is formed in ring shape in the plan view and surrounds the reference mark.

18. A semiconductor wafer, comprising:
a wafer body, having a plurality of element regions and a cutting predetermined region for dividing the plurality of element regions;
a first element pattern, formed in each of the plurality of element regions;
an outer mark, formed in the cutting predetermined region and in same layer as the first element pattern;
a second element pattern, formed in an upper region of the first element pattern; and
an outer pattern and a peripheral pattern, formed in same layer as the second element pattern and in the cutting predetermined region, wherein
the outer pattern overlaps with the outer mark in a plan view;
the peripheral pattern surrounds the outer mark in the plan view.

19. A semiconductor device, comprising:
a chip, having an element region and a peripheral region;
an element pattern, formed in the element region; and
a peripheral pattern, formed in the peripheral region in same layer as the element pattern and formed in a ring having ends in a plan view, wherein
one end and another end of the ring having ends of the peripheral pattern are exposed to an exterior side from a same end face of the chip,
and a portion between the one end and the another end is disposed at an interior side of the end surface of the chip.

20. The semiconductor device of claim 19, wherein the peripheral pattern includes a first peripheral pattern and a second peripheral pattern surrounding the first peripheral pattern.
